(19) United States
(12) Patent Application Publication
(10) Pub. No.: US 2026/0290405 A1
(43) Pub. Date: Sep. 24, 2026

(54) MEMORY DEVICE

(71) Applicant: Kioxia Corporation, Tokyo (JP)

(72) Inventors: Kiichi SATO, Yokkaichi Mie (JP); Mutsumi OKAJIMA, Yokkaichi Mie (JP); Tsuyoshi SUGISAKI, Yokkaichi Mie (JP); Yuma TAKAHASHI, Yokkaichi Mie (JP)

(73) Assignee: Kioxia Corporation, Tokyo (JP)

(21) Appl. No.: 19/287,957

(22) Filed: Aug. 1, 2025

(30) Foreign Application Priority Data
Mar. 21, 2025 (JP) 2025-047274

(51) Int. Cl. G11C 5/06; H10B 12/00

(52) U.S. Cl. CPC G11C 5/063; H10B 12/02; H10B 12/30

(57) ABSTRACT

A semiconductor spreads along a first plane including first and second directions, has an annular shape, includes a first portion on a side in the first direction, and includes a second portion on a side opposite to the first direction. A first insulator is on the first portion of the semiconductor. A second insulator is on the second portion of the semiconductor. A first conductor is provided farther in a third direction than the first and second insulators, and includes a first conductor including a first portion facing the first portion of the semiconductor via the first insulator. A second conductor contacts the first conductor. A third conductor contacts the first portion of the semiconductor. A third insulator sandwiches the third conductor together with the first portion of the semiconductor. A fourth conductor sandwiches the third insulator together with the third conductor.

### CROSS-REFERENCE TO RELATED APPLICATIONS

This application is based upon and claims the benefit of priority from Japanese Patent Application No. 2025-47274, filed Mar. 21, 2025, the entire contents of which are incorporated herein by reference.

### FIELD

Embodiments described herein relate generally to a memory device.

### BACKGROUND

There is known a memory device including three-dimensionally arrayed memory cells to improve the degree of integration of the memory cells.

### BRIEF DESCRIPTION OF THE DRAWINGS

FIG. 1 illustrates components and coupling of the components of a memory device according to the first embodiment.

FIG. 2 illustrates components and coupling of the components of a memory cell of the memory device according to the first embodiment.

FIGS. 3 and 4 each schematically illustrate the structure of a section of a part of the memory device according to the first embodiment.

FIGS. 5, 6, and 7 each schematically illustrate the structure of a section of a part of the memory device according to the first embodiment.

FIGS. 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50, 51, 52, 53, 54, 55, 56, 57, 58, 59, 60, 61, 62, 63, 64, 65, 66, 67, 68, 69, 70, and 71 each illustrate the section of the structure of a part in manufacturing steps of the memory device according to the first embodiment.

FIGS. 72 and 73 each schematically illustrate the structure of a section of a part of a memory device according to the second embodiment.

FIGS. 74, 75, 76, 77, 78, 79, 80, 81, 82, and 83 each illustrate the section of the structure of a part in the manufacturing steps of the memory device according to the second embodiment.

### DETAILED DESCRIPTION

In general, according to one embodiment, a memory device includes a semiconductor, a first insulator, a second insulator, a first conductor, a second conductor a third conductor, a third insulator, and a fourth conductor. The semiconductor spreads along a first plane including a first direction and a second direction which cross each other, has an annular shape, includes a first portion on a side in the first direction, and includes a second portion on a side opposite to the first direction. The first insulator is on the first portion of the semiconductor. The second insulator is on the second portion of the semiconductor. The first conductor is provided farther in a third direction crossing the first direction and the second direction than the first insulator and the second insulator, and includes a first conductor including a first portion facing the first portion of the semiconductor via the first insulator. The second conductor contacts the first conductor. The third conductor contacts the first portion of the semiconductor. The third insulator sandwiches the third conductor together with the first portion of the semiconductor. The fourth conductor sandwiches the third insulator together with the third conductor.

Embodiments will now be described with reference to the figures. In order to distinguish components having substantially the same function and configuration in an embodiment or over different embodiments from each other, an additional numeral or letter may be added to the end of each reference numeral or letter. In the following description, in an embodiment following an embodiment that is already described, different points from the already described embodiment are mainly described. The entire description of a particular embodiment applies to another embodiment unless an explicit mention is made otherwise, or an obvious elimination is involved.

The figures are schematic, and the relation between the thickness and the area of a plane of a layer and the ratio of thicknesses of layers may differ from those in actuality. The figures may include components which differ in relations positions and/or ratios of dimensions in different figures.

The specification and the claims, when mentioning that a particular (first) component is “coupled” to another (second) component, intend to cover both the form of the first component directly coupled to the second component and the form of the first component coupled to the second component via one or more components which are always or selectively conductive.

### 1. FIRST EMBODIMENT

### 1.1. Configuration (Structure)

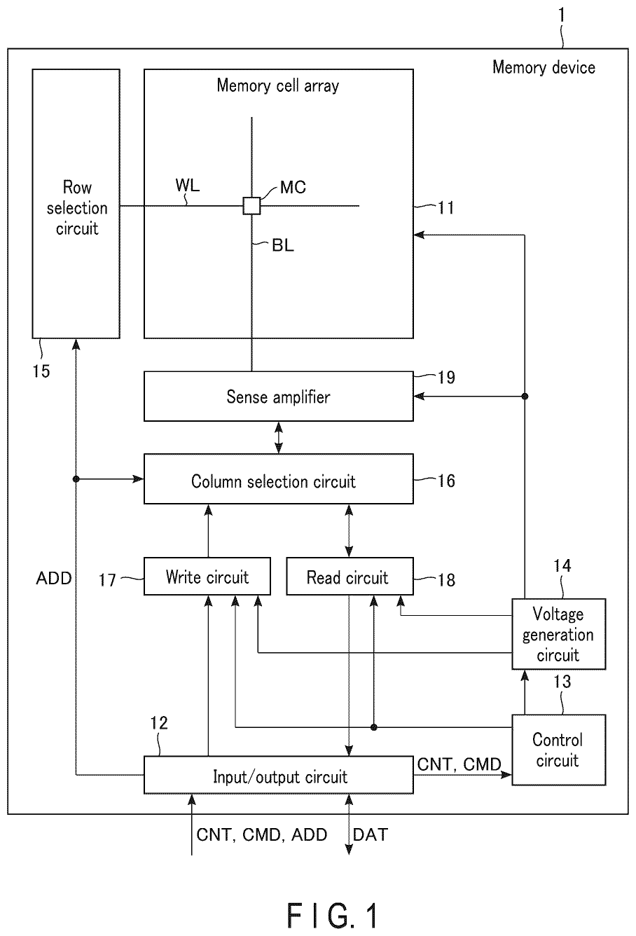

FIG. 1 illustrates components and coupling of the components of a memory device of a first embodiment. A memory device 1 is a device that stores data. The memory device 1 includes a memory cell array 11, an input/output circuit 12, a control circuit 13, a voltage generation circuit 14, a row selection circuit 15, a column selection circuit 16, a write circuit 17, a read circuit 18, and a sense amplifier 19.

The memory cell array 11 is a component that stores data. The memory cell array 11 includes a plurality of memory cells MC. Each memory cell MC is capable of storing 1-bit data. The memory cell array also includes interconnects such as word lines WL and bit lines BL. Each memory cell MC is coupled to a single bit line BL and a single word line WL. The memory cell MC is coupled between the bit line BL and the plate line PL (not illustrated).

The input/output circuit 12 is a circuit that inputs and outputs data and signals. The input/output circuit 12 receives a control signal CNT, a command CMD, an address signal ADD, and data DAT from the outside of the memory device 1. The input/output circuit 12 outputs data DAT.

The control circuit 13 is a circuit that controls the operation of the memory device 1. The control circuit 13 receives a command CMD and a control signal CNT from the input/output circuit 12. The control circuit 13 controls the write circuit 17 and the read circuit 18 based on control instructed by the command CMD and the control signal CNT.

The voltage generation circuit 14 is a circuit that generates various voltages used in the memory device 1. The voltage generation circuit 14 generates multiple voltages with different magnitudes under the control of the control circuit 13. The voltage generation circuit 14 supplies the generated voltages to the memory cell array 11, the write circuit 17, the read circuit 18, and the sense amplifier 19.

The row selection circuit 15 is a circuit that selects a row of a memory cell MC. The row selection circuit 15 receives an address signal ADD from the input/output circuit 12. The row selection circuit 15 makes a single word line WL associated with a row designated by the received address signal ADD a selected state, using a voltage received from the voltage generation circuit 14.

The column selection circuit 16 is a circuit that selects a column of a memory cell MC. The column selection circuit 16 receives an address signal ADD from the input/output circuit 12. The column selection circuit 16 makes a bit line BL associated with a column designated by the received address signal ADD a selected state, using a voltage received from the voltage generation circuit 14.

The write circuit 17 is a circuit that performs processing and control for writing data into the memory cells MC. The write circuit 17 supplies, based on the control of the control circuit 13 and data to be written, the voltage received from the voltage generation circuit 14 to the column selection circuit 16.

The read circuit 18 is a circuit that performs processing and control for reading data from the memory cells MC. The read circuit 18 supplies voltages received from the voltage generation circuit 14 to the column selection circuit 16 based on control of the control circuit 13. The read circuit 18 supplies a plurality of control signals for data read to the sense amplifier 19.

The sense amplifier 19 is a circuit for determining what data is stored in the memory cell MC. The sense amplifier 19 includes a plurality of sense amplifier circuits SAC (not illustrated). The sense amplifier 19 receives a plurality of voltages from the voltage generation circuit 14, and operates using the received voltages.

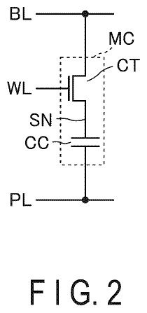

FIG. 2 illustrates components and coupling of the components of the memory cell of the memory device according to the first embodiment. Hereinafter, one of a source and a drain of a transistor may be referred to as one end of the transistor, and the other of the source and the drain may be referred to as the other end of the transistor.

As illustrated in FIG. 2, each memory cell MC includes a cell capacitor CC and an n-type metal-oxide-semiconductor field-effect transistor (MOSFET) CT. The cell capacitor CC is coupled to, at one end, a plate line PL, and is coupled to, at another end, one end of the transistor CT. The cell capacitor CC stores data using a charge stored in a node coupled to the transistor CT.

Whether or not the storage node SN stores a charge is associated with a state in which the memory cell MC stores “1” data, or a state in which “0” data is stored.

The transistor CT is coupled to, at the other end, a single bit line BL, and is coupled to, at its gate, a single word line WL.

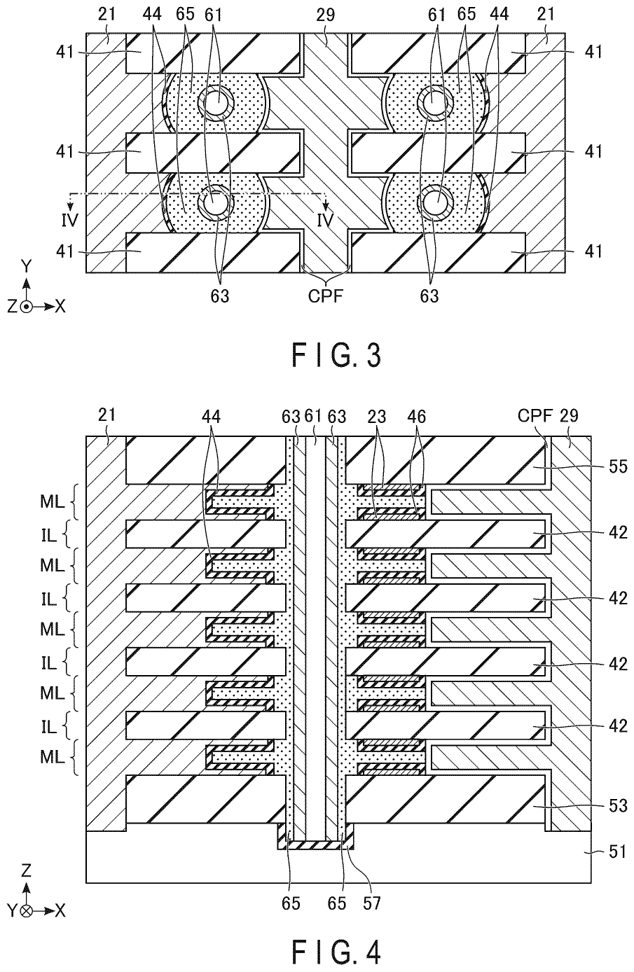

FIG. 3 schematically illustrates the structure of a section of a part of the memory device according to the first embodiment. FIG. 3 shows a section along an XY plane. The XY plane is orthogonal to the z-axis and includes x- and y-axes that are orthogonal to each other. The x-axis extends in the X direction, and the y-axis extends in the Y direction. A direction opposite to the X direction will be referred to as the −X direction. A direction opposite to the Y direction will be referred to as the −Y direction. A direction opposite to the Z direction will be referred to as the −Z direction. The Z direction may be expressed by a direction indicated by “up” or an associated term. The −Z direction may be expressed by a direction indicated by “down” or an associated term. FIG. 3 shows a memory layer ML to be described later. The structure shown in FIG. 3 is a structure in line symmetry with respect to a virtual line that passes through the center in the X direction and extends in the Y direction.

As shown in FIG. 3, the memory device includes insulators 41 and 44, vertical structures 61, conductors 21, 29, and 63, semiconductors 65, and a stacked film CPF. A semiconductor that obtains conductivity by containing a dopant is also included in the conductors.

The insulators 41 extend in the X direction and are arranged at intervals in the X and Y directions. The insulator 41 has a plate shape spreading along the XZ plane. In one example, the insulator 41 contains silicon oxide. The insulators 41 separate components (for example, the semiconductors 65 to be described later) that are arranged in the Y direction and sandwich the insulators 41.

The vertical structures 61 are arranged along the X and Y directions. The vertical structure 61 has a circular shape along the XY plane. The vertical structure 61 includes a space and/or an insulator.

Each conductor 63 surrounds a single vertical structure 61 along the XY plane and has an annular shape. The conductor 63 functions as at least a part of a single bit line BL. In one example, the conductor 63 contains at least one of tungsten (W), molybdenum (Mo), and ruthenium (Ru).

The semiconductor 65 surrounds a single conductor 63 along the XY plane and has a shape obtained by removing parts of an annular shape by the insulators 41. The semiconductors 65 arranged in the Y direction are insulated by the insulators 41. The semiconductor 65 functions as a region where the channel of a single transistor CT is formed. In one example, the semiconductor 65 includes an oxide semiconductor. Examples of the oxide semiconductor include oxides containing at least one of indium (In), gallium (Ga), zinc (Zn), tin (Sn), titanium (Ti), tungsten, and molybdenum. More practical examples of the oxide semiconductor include In—O, Ga—O, Zn—O, Sn—O, INO (Indium Tin Oxide), In—Ga—Zn—O, Ti—O, W—O, and Mo—O.

The conductor 29 spreads along the YZ plane and extends in the Y direction. The conductor 29 is located between two semiconductors 65 arranged in the X direction. The conductor 29 functions as at least a part of the plate line PL and as at least a part of the cell capacitor CC. The conductor 29 projects in the X and −X directions in a region between the insulators 41. The conductor 29 faces the semiconductor 65 at the projecting portion.

The stacked film CPF covers the conductor 29 and contacts the conductor 29 and the semiconductor 65. The stacked film CPF has a stacked structure of a conductor and an insulator, and functions as a single cell capacitor CC in each of a plurality of portions.

The conductor 21 spreads along the XY plane and extends in the Y direction. The conductor 21 projects toward the semiconductors 65. The conductor 21 sandwiches the semiconductor 65 together with the conductor 29 at the projecting portion. The conductor 21 functions as at least a part of the word line WL. The conductor 21 also functions as at least a part of the gate electrode of the transistor CT. In one example, the conductor 21 contains at least one of tungsten, molybdenum, and ruthenium.

Each insulator 44 is located between a single semiconductor 65 and the conductor 21. In one example, the insulator 44 contains silicon nitride.

FIG. 4 schematically illustrates the structure of a section of a part of the memory device according to the first embodiment. FIG. 4 shows a section along the XY plane. FIG. 4 shows a structure along a line IV-IV in FIG. 3. As shown in FIG. 4, the memory device 1 further includes insulators 55, 57, 42, and 46 and a conductor 23.

A substrate 51 spreads along the XY plane. In one example, the substrate 51 contains silicon.

An insulator 53 is located on the upper surface of the substrate 51. The insulator 53 spreads along the XY plane. In one example, the insulator 53 contains silicon oxide.

The insulators 42 are arranged at an interval in the Z direction in a region above the upper surface of the insulator 53. The insulator 42 spreads along the XY plane and has a plate shape. In one example, the insulator 42 contains silicon oxide. A layer in which the insulator 42 is located is called a layer IL. Layers between the layers IL and layers adjacent to the layers IL are called memory layers ML. The memory layer ML is a layer including a memory cell MC. FIG. 4 shows five memory layers ML as an example. The memory device 1 may include four or less or six or more memory layers ML.

The vertical structure 61 extends in the Z direction and has a columnar shape. In one example, the lower surface of the vertical structure 61 is located in the substrate 51.

The conductor 63 extends in the Z direction and has a tubular shape. The conductor 63 covers the side surface of the vertical structure 61. In one example, the lower surface of the conductor 63 is located in the substrate 51.

The semiconductor 65 extends in the Z direction and has a tubular shape. In the memory layer ML, the semiconductor 65 projects in directions away from the center of the vertical structure 61, and has, at the projecting portion, a tubular shape having a larger radius. The semiconductor 65 covers the side surface of the conductor 63. In one example, the lower surface of the semiconductor 65 is located in the substrate 51.

The insulator 55 is located in a layer immediately above the uppermost memory layer ML. The insulator 55 spreads along the XY plane and has a plate shape. In one example, the insulator 55 contains silicon oxide.

The insulator 57 covers portions of the vertical structure 61, the conductor 63, and the semiconductor 65 in the substrate 51. In one example, the insulator 57 contains silicon oxide.

The insulators 44 are located in the memory layers ML. Each insulator 44 covers a portion of the semiconductor 65 projecting on the side of the conductor 21.

The conductors 23 are located in the memory layers ML. Each conductor 23 functions as at least a part of the gate electrode of a single transistor CT. Each conductor 23 faces a portion of the semiconductor 65 projecting on the side of the conductor 29. Each of several conductors 23 is located on the upper surface or the lower surface of the insulator 42. Another conductor 23 is located on the upper surface of the insulator 53. Still another conductor 23 is located on the lower surface of the insulator 55. In one example, the conductor 23 contains titanium nitride.

The insulators 46 are located in the memory layers ML. Each insulator 46 functions as at least a part of the gate insulator of a single transistor CT. Each insulator 46 covers the surface of a single conductor 23. In one example, the insulator 46 contains silicon oxynitride. Each insulator 46 contacts a single conductor 23 and the semiconductor 65.

The conductor 21 extends in the Z direction. In each memory layer ML, the conductor 21 projects toward the semiconductor 65. The conductor 21 functions as at least a part of the word line WL.

The conductor 29 extends in the Z direction. In each memory layer ML, the conductor 29 projects toward the semiconductor 65.

The stacked film CPF covers the surface of the conductor 29. In each memory layer ML, the stacked film CPF contacts the semiconductor 65. The stacked film CPF functions as at least a part of the cell capacitor CC.

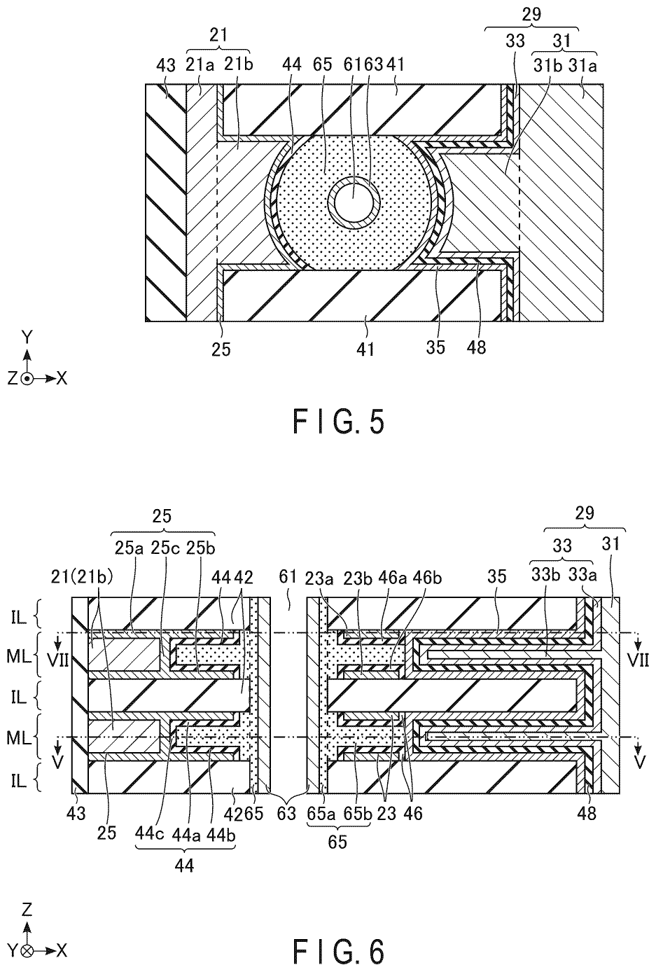

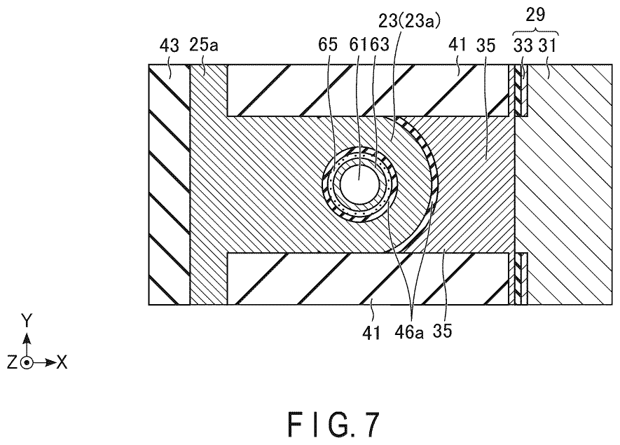

FIGS. 5, 6, and 7 each illustrate the structure of a section of a part of the memory device according to the first embodiment. FIG. 5 shows an enlarged view of a part of FIG. 3 and illustrates a structure along a lint V-V in FIG. 6. FIG. 6 shows an enlarged view of a part of FIG. 4. FIG. 7 shows the same region as that shown in FIG. 5 concerning the region along the XY plane and located farther in the Z direction than the region shown in FIG. 5, and illustrates a structure along a line VII-VII in FIG. 6. The XY plane shape of an element or the shape thereof viewed from the Z direction may be referred to as an XY plane shape hereinafter.

As shown in FIGS. 5, 6, and 7, the memory device 1 further includes conductors 25 and an insulator 43.

The semiconductor 65 includes a first portion 65a and a plurality of second portions 65b. The first portion 65a extends in the Z direction and has a tubular shape. The first portion 65a surrounds the vertical structure 61 along the XY plane. The first portion 65a contacts the conductor 63 along the Z direction. The first portion 65a contacts the insulator 42 at a portion in each layer IL.

Each second portion 65b has a tubular shape. The second portion 65b is located in the memory layer ML. The second portion 65b is connected on the inner side to the first portion 65a. The second portion 65b has an XY plane shape larger than the XY plane shape of the first portion 65a. In one example, the second portion 65b has, along the XY plane, a radius larger than the radius of the first portion 65a along the XY plane. The second portion 65b is partially located between two insulators 42 arranged in the Z direction. The second portion 65b functions as a region where the channel of a single transistor CT is formed.

The insulator 44 includes a first portion 44a, a second portion 44b, and a third portion 44c. The first portion 44a and the second portion 44b spread along the XY plane. The first portion 44a and the second portion 44b are curved. The XY plane shape of the first portion 44a and the second portion 44b conforms to the XY plane shape of the second portion 65b of the semiconductor 65. A single first portion 44a and a single second portion 44b sandwich a single second portion 65b of the semiconductor 65.

The first portion 44a is located on the side of the second portion 65b of the semiconductor 65 in the Z direction and contacts the second portion 65b. The first portion 44a faces a single insulator 42 on the side in the Z direction. The first portion 44a includes a portion extending in the Z direction at an end on the side closer to the vertical structure 61.

The second portion 44b is located on the side of the second portion 65b of the semiconductor 65 in the −Z direction and contacts the second portion 65b. The second portion 44b faces a single insulator 42 on the side in the −Z direction. The second portion 44b includes a portion extending in the −Z direction at an end on the side closer to the vertical structure 61.

The third portion 44c is located on a side farther from the vertical structure 61 than the first portion 44a and the second portion 44b. The third portion 44c is connected to the first portion 44a and the second portion 44b at an end on the side farther from the vertical structure 61. The XY plane shape of the third portion 44c conforms to the XY plane shape of the second portion 65b of the semiconductor 65 and is curved. The third portion 44c contacts the second portion 65b of the semiconductor 65 at an end on the side close to the vertical structure 61.

The conductors 23 include conductors 23a and 23b. The conductor 23a is located on the upper surface of the insulator 42 which is on the lower side of the memory layer ML. The conductor 23a is located between the insulator 42 which is on the lower side and the second portion 65b of the semiconductor 65.

The conductor 23b is located on the lower surface of the insulator 42 which is on the upper side of the memory layer ML. The conductor 23b is located between the insulator 42 which is on the upper side and the second portion 65b of the semiconductor 65. The XY plane shape of the conductor 23b is substantially the same as the XY plane shape of the conductor 23a. The description that a certain shape is substantially the same as another shape intends that the two shapes are the same, but includes a case where the two shapes are not completely the same due to limitations of the manufacturing technique.

The XY plane shape of the conductor 23 conforms to the XY plane shape of the second portion 65b of the semiconductor 65.

The insulators 46 include insulators 46a and 46b. The insulator 46a covers the lower surface and the side surface of the conductor 23a and contacts the lower surface and the side surface of the conductor 23a. The insulator 46b covers the upper surface and the side surface of the conductor 23b and contacts the upper surface and the side surface of the conductor 23b.

The insulator 46 is integral with the insulator 44. That is, the insulator 44 and the insulator 46 are different portions of an insulator. The insulators 46 and 44 being integral includes forming the insulators 46 and 44 by (a single) common process, as will be described later. The set of the insulator 44 and the insulator 46 has an annular shape along the XY plane, and surrounds, along the XY plane, a structure formed by the set of the vertical structure 61, the conductor 63, and the first portion 65a of the semiconductor 65. The insulator 46a and the first portion 44a of the insulator 44 are arranged in the −X direction. The insulator 46b and the second portion 44b of the insulator 44 are arranged in the −X direction.

The conductor 21 includes a first portion 21a and the second portion 21b. The first portion 21a extends in the Y direction.

The second portion 21b is connected to the first portion 21a at an end on the side farther from the vertical structure 61. The second portion 21b spreads along the XY plane. The second portion 21b has a shape conforming to the shape of the insulator 41 on a surface on the side in the Y direction and on a surface on the side in the −Y direction. The XY plane shape of the second portion 21b conforms to the XY plane shape of the third portion 44c of the insulator 44 on a surface on the side closer to the vertical structure 61 and is curved.

The insulator 43 spreads along the YZ plane. The insulator 43 contacts the conductor 21 at an end on the side closer to the vertical structure 61. In one example, the insulator 43 contains silicon oxide.

The conductor 25 includes a first portion 25a, a second portion 25b, and a third portion 25c.

The first portion 25a is the uppermost portion of the conductor 25. The first portion 25a spreads between the insulator 42 on the upper side and the second portion 21b of the conductor 21 and between the insulator 42 on the upper side and the second portion 65b of the semiconductor 65. The first portion 25a contacts the insulator 42 on the upper side, the second portion 21b of the conductor 21, and the first portion 44a of the insulator 44.

The second portion 25b is the lowermost portion of the conductor 25. The second portion 25b spreads between the insulator 42 on the lower side and the second portion 21b of the conductor 21 and between the insulator 42 on the lower side and the second portion 65b of the semiconductor 65. The second portion 25b contacts the insulator 42 on the lower side, the second portion 21b of the conductor 21, and the second portion 44b of the insulator 44. The XY plane shape of the second portion 25b conforms to the XY plane shape of the first portion 25a and, in one example, is substantially the same as the XY plane shape of the first portion 25a.

The third portion 25c is a portion located in the same layer as the second portion 65b of the semiconductor 65. The third portion 25c is located between the first portion 25a and the second portion 25b and connected to the first portion 25a and the second portion 25b. The third portion 25c is located between the second portion 21b of the conductor 21 and the third portion 44c of the insulator 44. The third portion 25c contacts the second portion 21b of the conductor 21 and the third portion 44c of the insulator 44. The third portion 25c has a layered shape along the XY plane. The third portion 25c extends along the insulator 41 in regions at ends on the side in the Y direction and on the side in the −Y direction. In a region on the side closer to the vertical structure 61, the XY plane shape of the third portion 25c conforms to the XY plane shape of the third portion 44c of the insulator 44 and is curved.

The conductor 25 functions as at least a part of the word line WL. The conductor 25 contains titanium nitride.

The conductor 25 is integral with the conductor 23. That is, the conductor 25 and the conductor 23 are different portions of a conductor. The first portion 25a of the conductor 25 is connected to the conductor 23a. The second portion 25b of the conductor 25 is connected to the conductor 23b. The set of the first portion 25a of the conductor 25 and the conductor 23a surrounds, along the XY plane, a structure formed by the set of the vertical structure 61, the conductor 63, and the first portion 65a of the semiconductor 65. The set of the second portion 25b of the conductor 25 and the conductor 23b surrounds, along the XY plane, a structure formed by the set of the vertical structure 61, the conductor 63, and the first portion 65a of the semiconductor 65.

The conductor 25 and the conductor 23 being integral includes forming the conductors 25 and 23 by (a single) common process, as will be described later. Since the conductor 25 and the conductor 23 are integral, in one example, the conductor functioning as the conductors 25 and 23 does not include a seam that would be generated when the conductors 25 and 23 are formed by different processes. Also, since the conductor 25 and the conductor 23 are integral, in one example, the conductor functioning as the conductors 25 and 23 has a common crystal orientation and does not have different crystal orientations that would be generated when the conductors 25 and 23 are formed by different processes.

The conductor 29 includes the conductor 31 and a conductor 33. The conductor 31 includes a first portion 31a and a second portion 31b. The first portion 31a spreads along the YZ plane and has a plate shape.

The second portion 31b spreads along the XY plane. The second portion 31b is connected to the first portion 31a at an end on the side farther from the vertical structure 61. The second portion 31b faces the insulator 41 located on the side in the Y direction at an end on the side in the Y direction. The second portion 31b faces the insulator 41 located on the side in the −Y direction at an end on the side in the −Y direction. The shape of the second portion 31b along the XY plane conforms to the outer shape of the second portion 65b of the semiconductor 65 along the XY plane at an end on the side closer to the vertical structure 61 and is curved.

The conductor 31 contains titanium nitride and/or tungsten. In one example, the conductor 31 has a structure formed by stacking a layer of titanium nitride and a layer of tungsten.

The conductor 33 covers the surface of the conductor 31. The conductor 33 is partially located between the insulator 42 on the upper side and the second portion 31b of the conductor 31. The conductor 33 is partially located between the insulator 42 on the lower side and the second portion 31b of the conductor 31. The conductor 33 is partially located between the second portion 65b of the semiconductor 65 and the conductor 33. In the conductor 33, the XY plane shape of the portion between the second portion 65b of the semiconductor 65 and the second portion 31b of the conductor 31 conforms to the XY plane shape of the insulator 41 on the side in the Y direction and the XY plane shape of the insulator 41 on the side in the −Y direction. In the conductor 33, the XY plane shape of the portion between the second portion 65b of the semiconductor 65 and the second portion 31b of the conductor 31 conforms to the XY plane shape of the outer shape of the second portion 65b of the semiconductor 65 and is curved.

The conductor 33 functions as an electrode on the side of the plate line PL among the two electrodes of the cell capacitor CC. In one example, the conductor 33 contains titanium nitride and/or tungsten.

The stacked film CPF includes an insulator 48 and a conductor 35.

The insulator 48 covers the surface of the conductor 33. The insulator 48 is partially located between the insulator 42 on the upper side and the second portion 31b of the conductor 31. The insulator 48 is partially located between the insulator 42 on the lower side and the second portion 31b of the conductor 31. The insulator 48 is partially located between the second portion 65b of the semiconductor 65 and the second portion 31b of the conductor 31. In the insulator 48, the XY plane shape of the portion between the second portion 65b of the semiconductor 65 and the second portion 31b of the conductor 31 conforms to the XY plane shape of the insulator 41 on the side in the Y direction and the XY plane shape of the insulator 41 on the side in the −Y direction. In the insulator 48, the XY plane shape of the portion between the second portion 65b of the semiconductor 65 and the second portion 31b of the conductor 31 conforms to the XY plane shape of the outer shape of the second portion 65b of the semiconductor 65 and is curved.

The insulator 48 functions as the insulator of the cell capacitor CC. In one example, the insulator 48 contains at least one of zirconium oxide (zirconia) and aluminum oxide (alumina). In one example, the insulator 48 has a stacked structure of a layer of zirconium oxide and a layer of aluminum oxide.

The conductor 35 covers the surface of the insulator 48. The XY plane shape of the conductor 35 conforms to the XY plane shape of the insulator 48. The XY plane shape of the conductor 35 conforms to the XY plane shape of the outer shape of the second portion 65b of the semiconductor 65 and is curved. The conductor 35 is insulated from the conductor 33 by the insulator 48. The conductor 35 functions as an electrode of the cell capacitor CC on the side of the transistor CT. In one example, the conductor 35 contains a conductive oxide. Examples of the conductive oxide include indium tin oxide (ITO).

### 1.2. Manufacturing Method

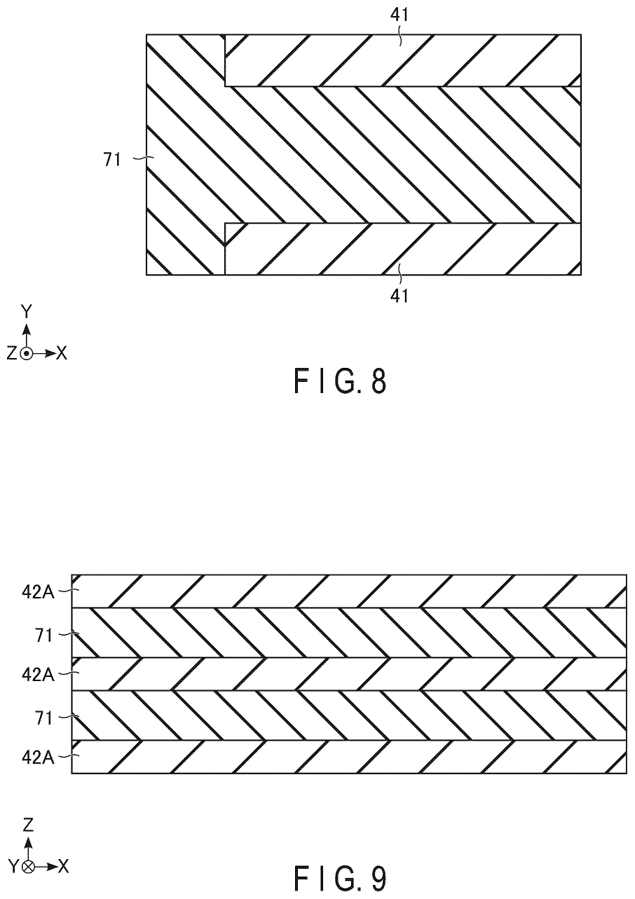

FIGS. 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50, 51, 52, 53, 54, 55, 56, 57, 58, 59, 60, 61, 62, 63, 64, 65, 66, 67, 68, 69, 70, and 71 each illustrate the section of the structure of a part in the manufacturing steps of the memory device according to the first embodiment.

FIGS. 8, 10, 12, 14, 16, 19, 21, 23, 25, 27, 29, 31, 33, 35, 38, 40, 42, 44, 46, 48, 50, 52, 54, 56, 58, 60, 62, 64, 66, 68, and 70 each show the region shown in FIG. 5.

FIGS. 9, 11, 13, 15, 17, 20, 22, 24, 26, 28, 30, 32, 34, 36, 39, 41, 43, 45, 47, 49, 51, 53, 55, 57, 59, 61, 63, 65, 67, 69, and 71 each show the region shown in FIG. 6.

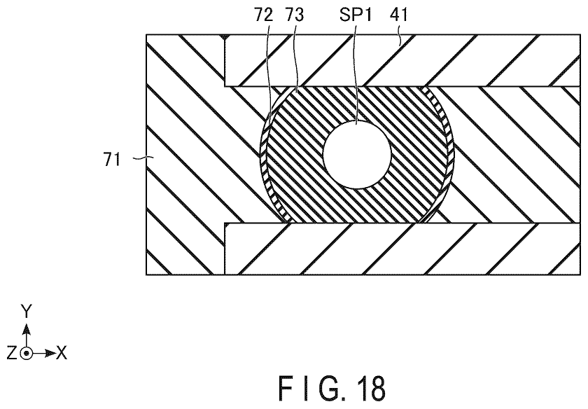

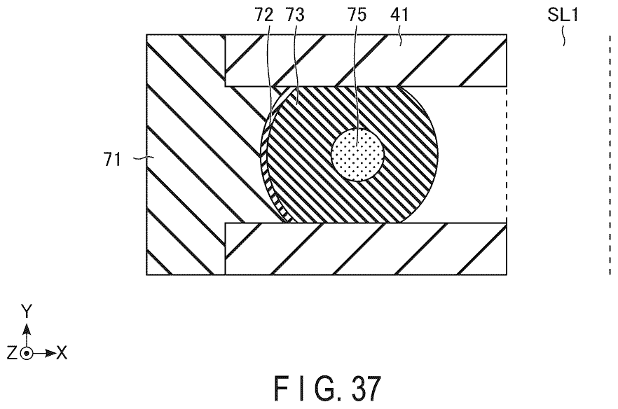

FIGS. 18 and 37 each show the region shown in FIG. 7.

As shown in FIGS. 8 and 9, an insulator 42A and a sacrificial material 71 are alternately deposited one by one above a substrate 51 (not shown). The insulator 42A is a component to be processed to an insulator 42 by a later step, and contains the same material as the insulator 42. The sacrificial material 71 is located in the region of a memory layer ML. The sacrificial material 71 contains a material different from the insulator 42 and, in one example, contains silicon nitride. Examples of a method of deposition include chemical vapor deposition (CVD).

Insulators 41 are formed. That is, first, a slit is formed in a region where each insulator 41 is planned to be formed. The slit extends through the insulators 42A and the sacrificial materials 71 in the Z direction. A method of forming the slit includes a set of a lithography process and anisotropic etching. Examples of anisotropic etching include reactive ion etching (RIE).

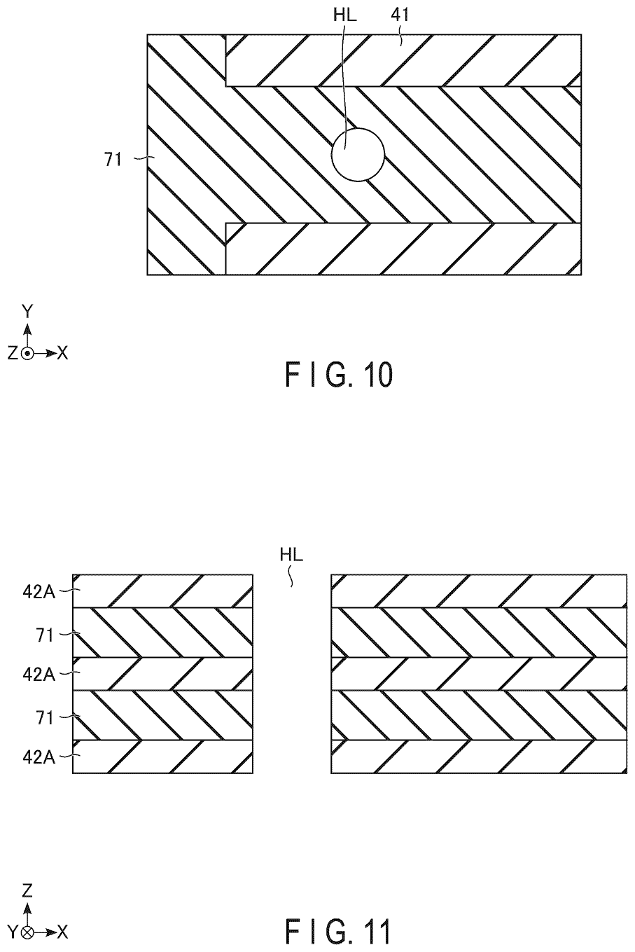

As shown in FIGS. 10 and 11, a hole HL is formed. The hole HL is located in a region where a vertical structure 61 is planned to be formed, and extends through the insulators 42A and the sacrificial materials 71 in the Z direction. Examples of a method of forming the hole HL include a lithography process and anisotropic etching such as RIE.

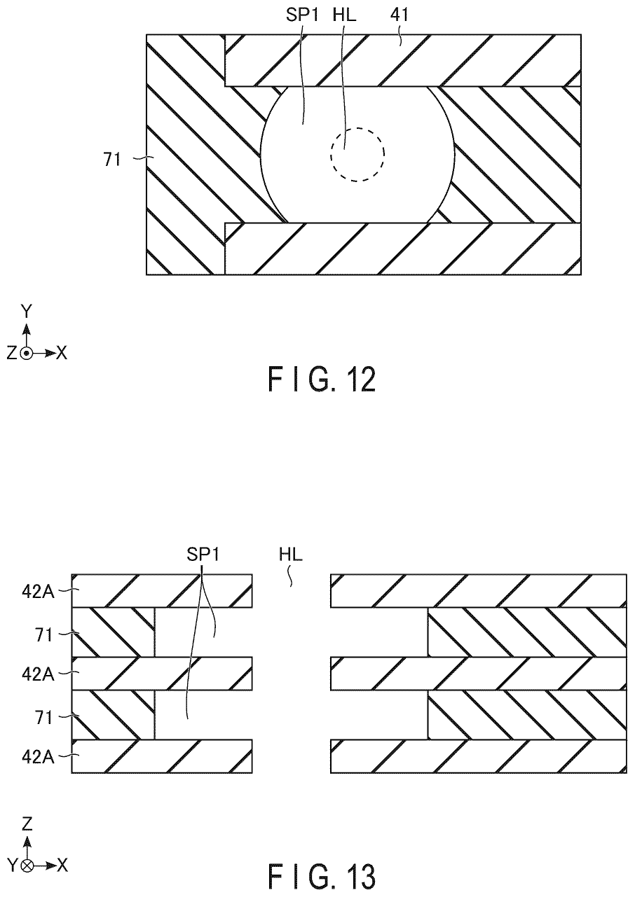

As shown in FIGS. 12 and 13, the sacrificial materials 71 are partially removed, thereby forming spaces SP1 in the removed regions. The space SP1 spreads from the center of the hole HL along the XY plane. The space SP1 is located in a region where a second portion 65b of a semiconductor 65 is planned to be formed. In the space SP1, the insulator 41 is exposed. Examples of a method of forming the space SP1 include wet etching.

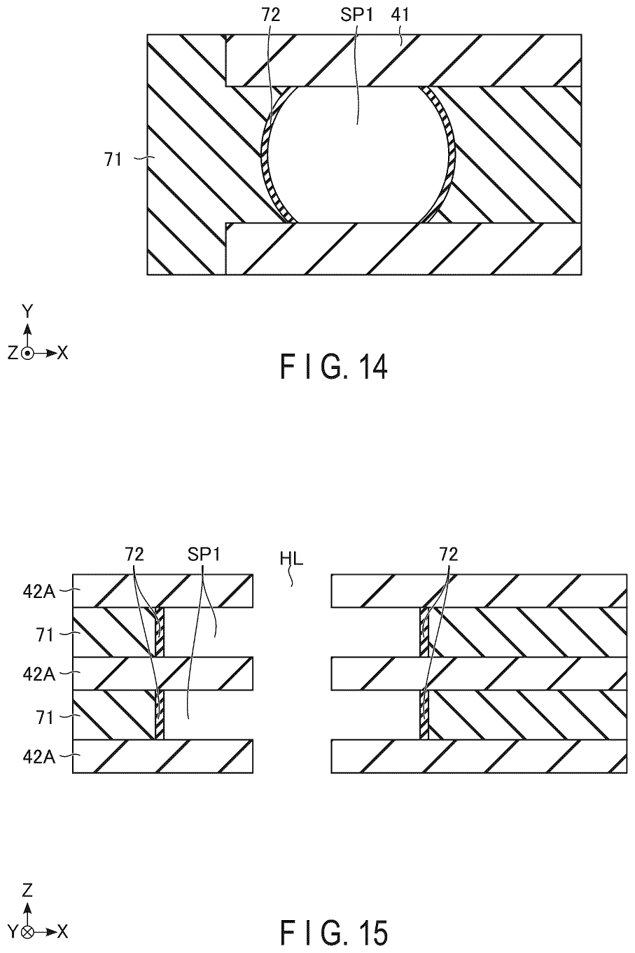

As shown in FIGS. 14 and 15, a sacrificial material 72 is deposited. The sacrificial material 72 is deposited on a portion of each sacrificial material 71 exposed in the space SP1. The sacrificial material 72 has an annular shape along the XY plane. In one example, the sacrificial material 72 is formed by radical oxidation of the surface of the sacrificial material 71 and, in this case, contains silicon oxynitride.

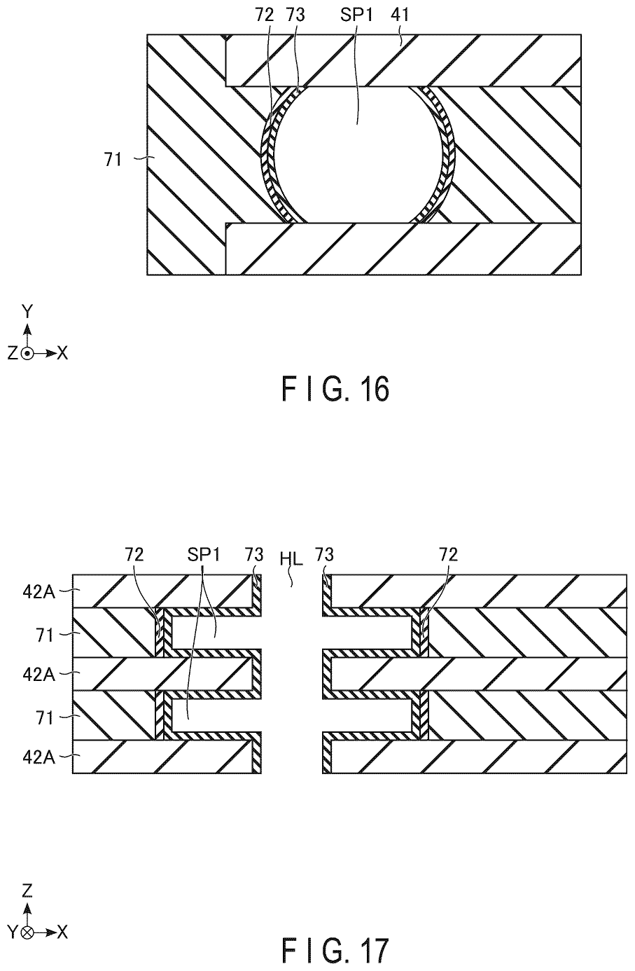

As shown in FIGS. 16, 17, and 18, a sacrificial material 73 is deposited. The sacrificial material 73 is located on the surfaces of components that define the hole HL and the spaces SP1. That is, the sacrificial material 73 is located on portions of the insulators 42A exposed in the hole HL and the spaces SP1. Also, the sacrificial material 73 is located on a portion of each sacrificial material 72 exposed in the space SP1. The sacrificial material 73 has an annular shape along the XY plane. In one example, the sacrificial material 73 contains silicon nitride. Examples of a method of deposition include CVD in a low-pressure environment.

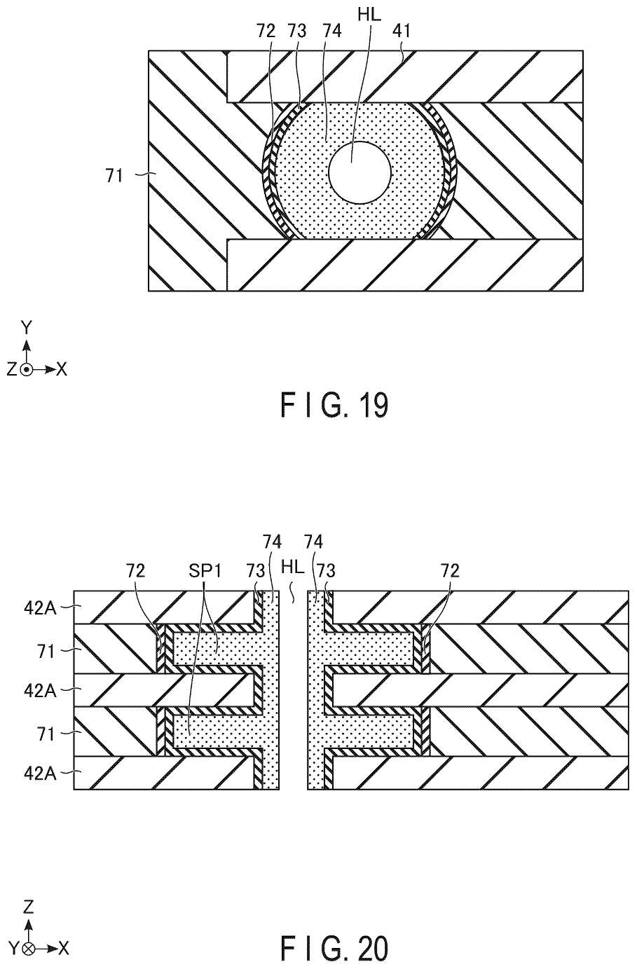

As shown in FIGS. 19 and 20, a sacrificial material 74 is deposited. The sacrificial material 74 buries the spaces SP1. Also, the sacrificial material 74 is located on the surface of a component that defines the hole HL. That is, the sacrificial material 74 is located on a portion of the sacrificial material 73 exposed in the hole HL. The sacrificial material 74 has an annular shape along the XY plane. The sacrificial material 74 does not bury the hole HL, and the hole HL partially remains. In one example, the sacrificial material 74 contains amorphous silicon. Examples of a method of depositing the sacrificial material 74 include CVD in a low-pressure environment.

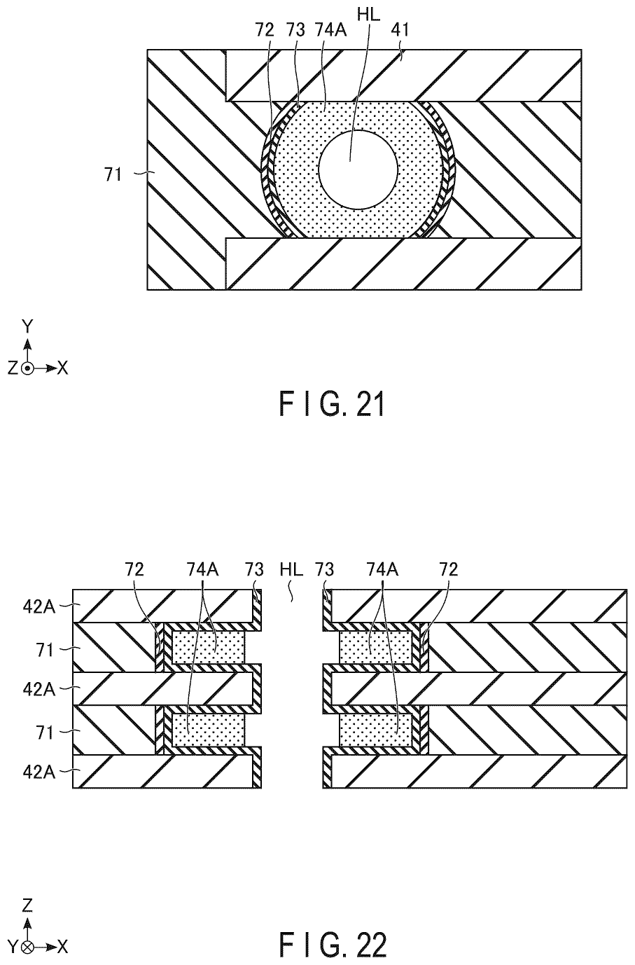

As shown in FIGS. 21 and 22, the sacrificial material 74 is partially removed such that it is removed from the hole HL and remains in the spaces SP1. A portion of the sacrificial material 74 in the hole HL (that is, a portion on a portion of the sacrificial material 73 in the hole HL) is removed, thereby forming, in each space SP1, a sacrificial material 74A from the sacrificial material 74. The sacrificial material 74A has an annular shape along the XY plane. The sacrificial material 74 is partially removed from the center of the hole HL toward the spaces SP1. Hence, the XY plane shape of the inner surface of the sacrificial material 74A is larger than the XY plane shape of the hole HL, and the space SP1 is partially formed again in the region connected to the hole HL. Examples of a method of partially removing the sacrificial material 74 include wet etching.

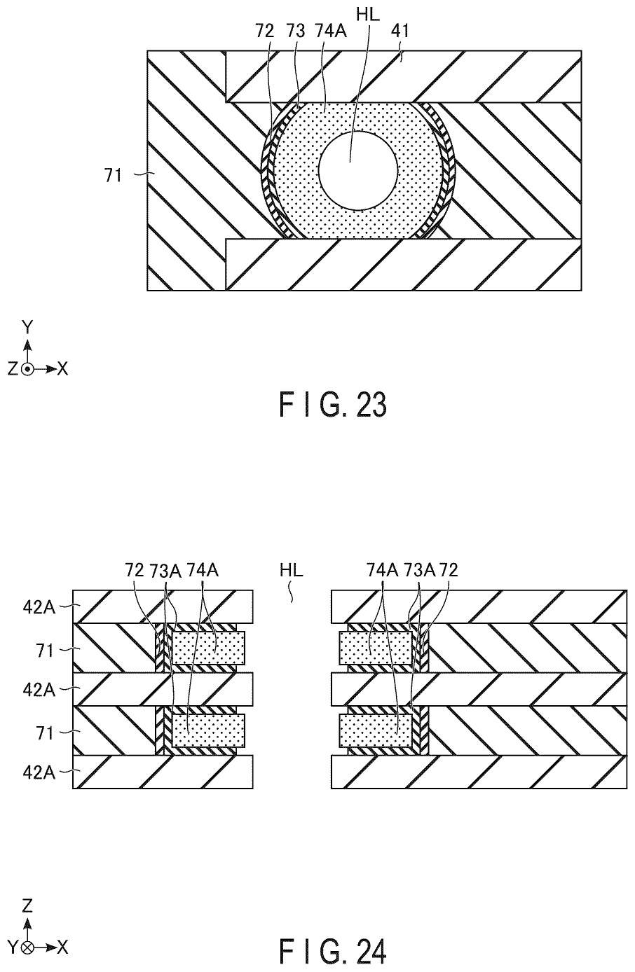

As shown in FIGS. 23 and 24, the sacrificial material 73 is partially removed such that it is removed from the hole HL and remains in the spaces SP1. A portion of the sacrificial material 73 in the hole HL (that is, a portion on a portion of each insulator 42A in the hole HL) is removed, thereby forming, in each space SP1, a sacrificial material 73A from the sacrificial material 73. The sacrificial material 73A has an annular shape along the XY plane. The sacrificial material 73A has a shape similar to a U shape, and includes a portion between the insulator 42A on the upper side and the sacrificial material 74A, a portion between the sacrificial material 71 and the sacrificial material 74A, and a portion between the insulator 42A on the lower side and the sacrificial material 74A. The sacrificial material 73 is partially removed from the center of the hole HL toward the spaces SP1. Hence, an end of the sacrificial material 73A is located outside the edge of the hole HL. Examples of a method of partially removing the sacrificial material 73 include wet etching.

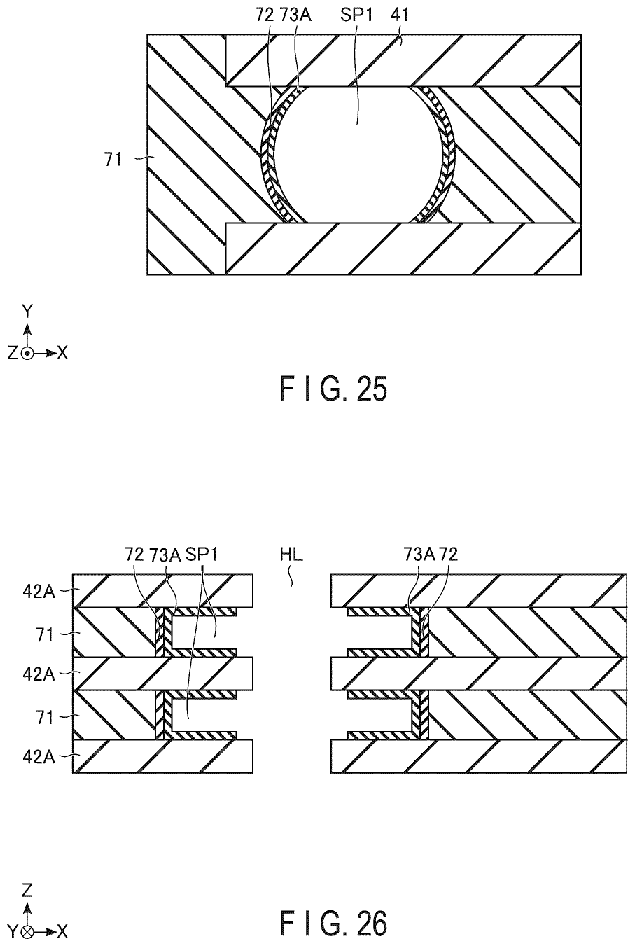

As shown in FIGS. 25 and 26, the sacrificial materials 74A are removed. By the removal, the spaces SP1 are partially formed again. Examples of a method of removing the sacrificial material 74A include wet etching.

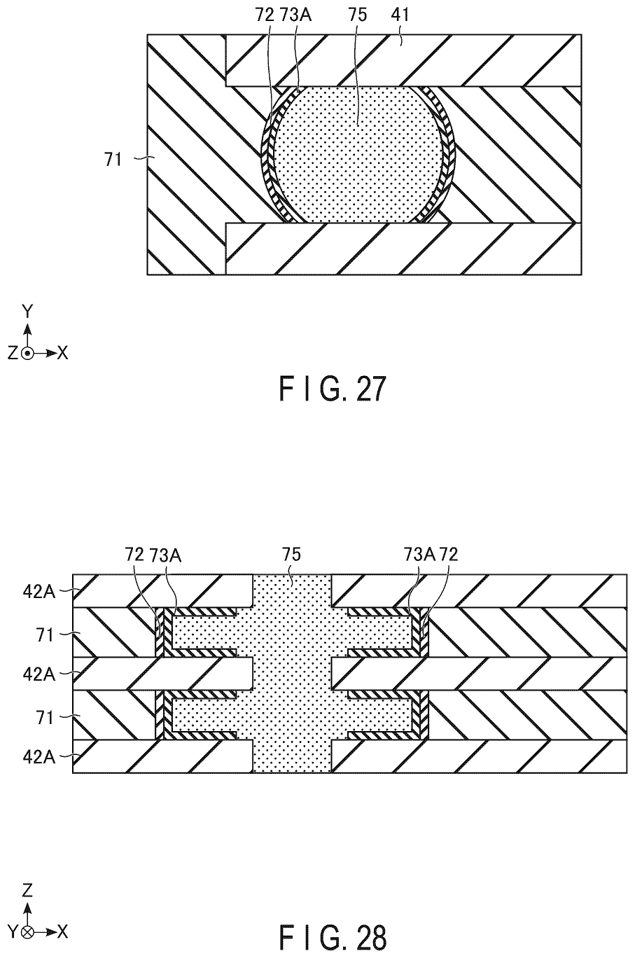

As shown in FIGS. 27 and 28, remaining portions of the hole HL and the spaces SP1 are buried by a sacrificial material 75. In one example, the sacrificial material 75 contains amorphous silicon. Examples of a method of burying the sacrificial material 75 include CVD in a low-pressure environment.

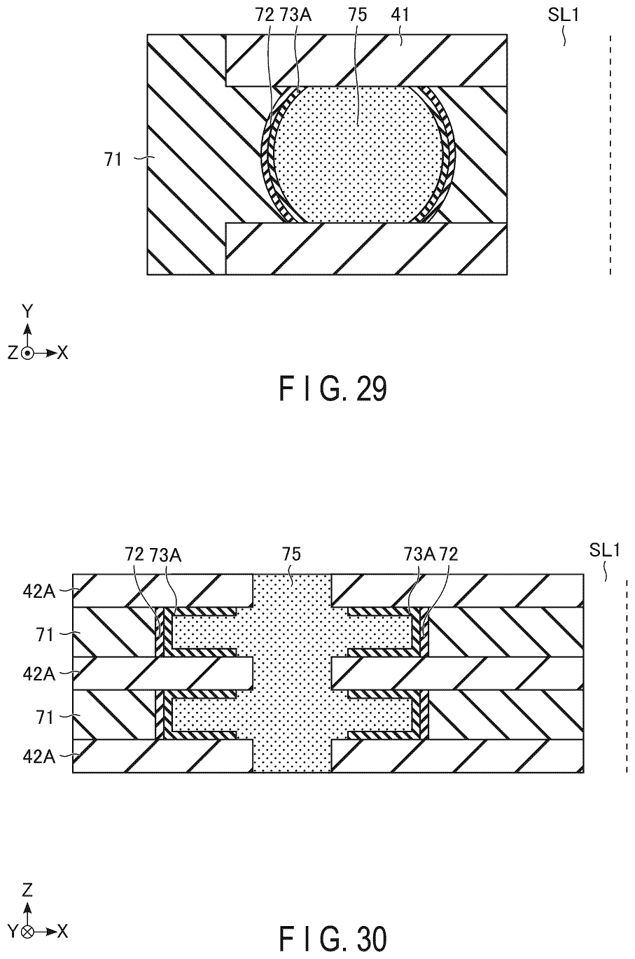

As shown in FIGS. 29 and 30, a slit SL1 is formed in the insulators 42A and 41 and the sacrificial materials 71. The slit SL1 spreads along the YZ plane and extends through the insulators 42A and 41 and the sacrificial materials 71. The slit SL1 is located in a region where a first portion 31a of a conductor 31, a portion of a conductor 33 between the insulator 42 and the first portion 31a of the conductor 31, a portion of an insulator 48 between the insulator 42 and the first portion 31a of the conductor 31, and a portion of a conductor 35 between the insulator 42 and the first portion 31a of the conductor 31 are planned to be formed. Examples of a method of forming the slit SL1 include a lithography process and anisotropic etching such as RIE.

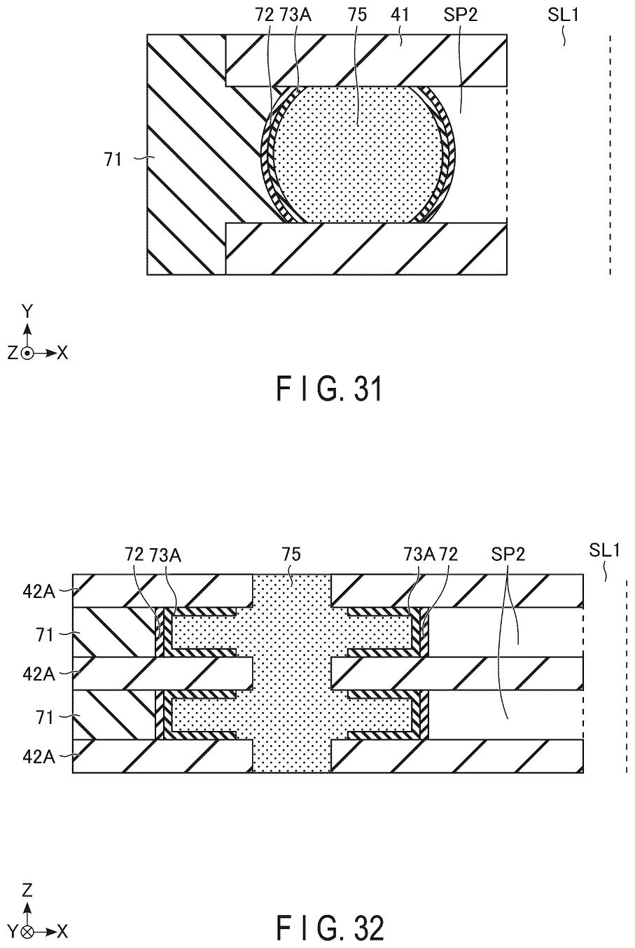

As shown in FIGS. 31 and 32, a portion of each sacrificial material 71 facing the slit SL1 is removed. The sacrificial material 71 is partially removed from the side of the slit SL1 until the sacrificial material 72 is exposed. By the removal, a space SP2 is formed in a region where the removed portion of each sacrificial material 71 was located. Examples of a method of partially removing the sacrificial material 71 include wet etching.

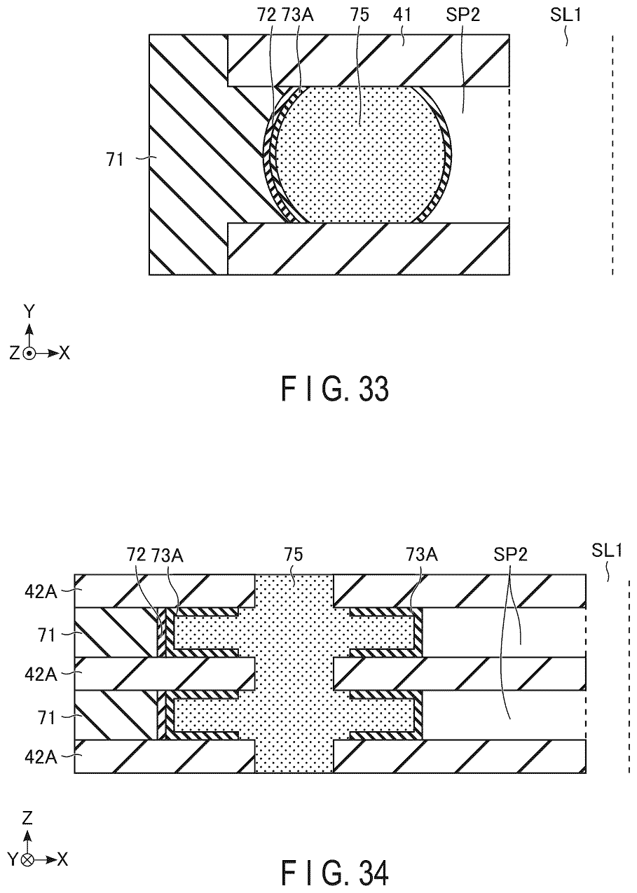

As shown in FIGS. 33 and 34, a portion of each sacrificial material 72 exposed in the space SP2 is removed. By the removal, the sacrificial material 73A is exposed in each space SP2. Examples of the method of removal include wet etching.

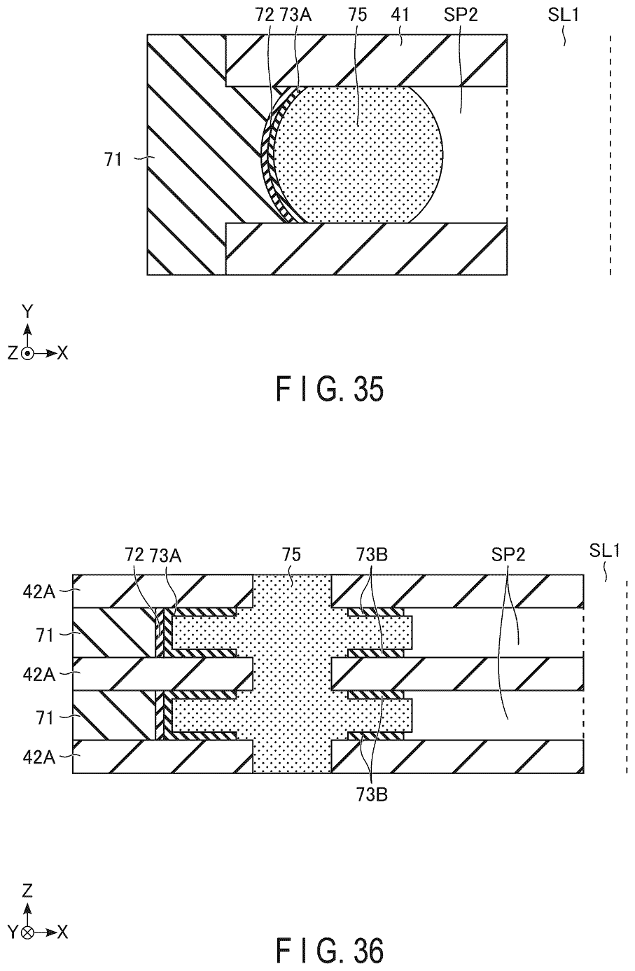

As shown in FIGS. 35, 36, and 37, a portion of each sacrificial material 73A exposed in the space SP2 is removed. A portion of the sacrificial material 73A including an end on the side of the slit SL1, that is, only a portion on a portion of the sacrificial material 75 on the side of the slit SL1 is removed. Thus, on the side of the slit SL1 with respect to the sacrificial material 75, a portion of the sacrificial material 73A on the lower surface of the insulator 42A on the upper side and a portion of the sacrificial material 73A on the upper surface of the insulator 42A on the lower side are separated from each other. As described above with reference to FIGS. 16, 17, and 18, the sacrificial material 73 has an annular shape along the XY plane. Hence, the portion of the sacrificial material 73A on the lower surface of the insulator 42A on the upper side is connected to the portion on the side of the sacrificial material 71 with respect to the sacrificial material 75, and still has an annular shape. Similarly, the portion of the sacrificial material 73A on the upper surface of the insulator 42A on the lower side is connected to the portion on the side of the sacrificial material 71 with respect to the sacrificial material 75, and still has an annular shape. Examples of a method of partially removing the sacrificial material 73A include wet etching. The portion of the sacrificial material 73A on the side of the sacrificial material 71 with respect to the sacrificial material 75 and on the lower surface of the insulator 42A on the upper side and the portion of the sacrificial material 73A on the side of the sacrificial material 71 with respect to the sacrificial material 75 and on the upper surface of the insulator 42A on the lower side will each may be referred to as a sacrificial material 73B hereinafter.

By the partial removal of the sacrificial material 73A, the space SP2 becomes wide, and the sacrificial material 75 is exposed in the space SP2.

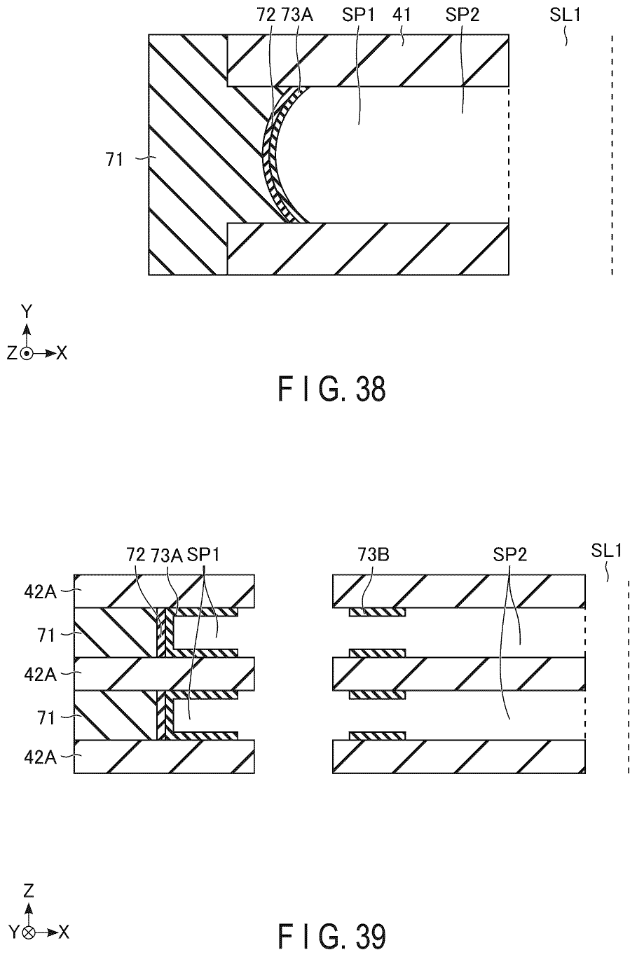

As shown in FIGS. 38 and 39, the sacrificial material 75 is removed. By the removal, the hole HL is formed again, and the spaces SP1 are partially formed again. The spaces SP1 and SP2 are connected. Examples of a method of removing the sacrificial material 75 include wet etching.

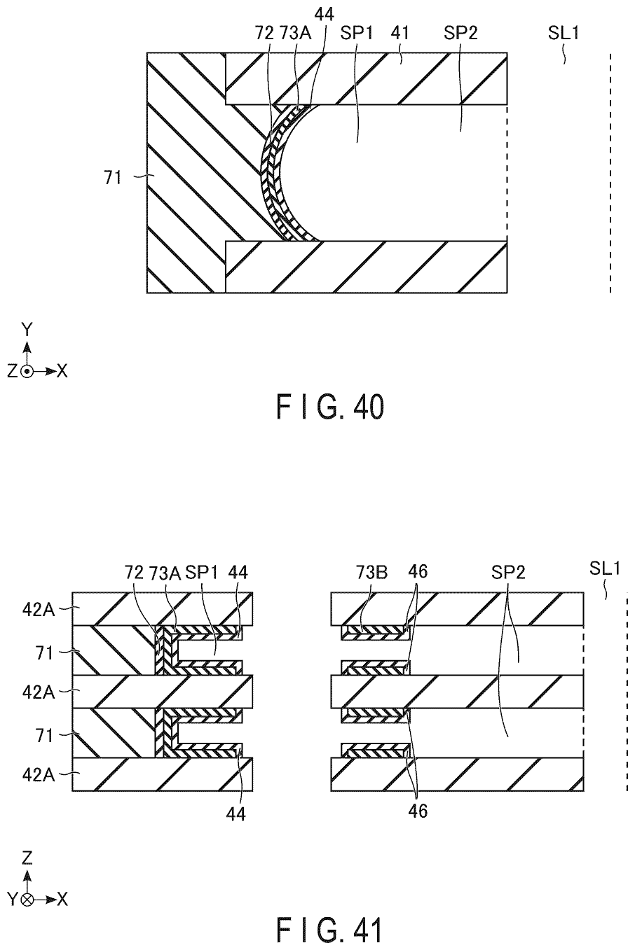

As shown in FIGS. 40 and 41, insulators 44 and 46 are deposited. As described above with reference to FIGS. 5, 6, and 7, the insulators 44 and 46 are different portions of a single insulator, and an insulator functioning as the insulators 44 and 46 is deposited on the surfaces of the sacrificial materials 73A and 73B. A method of deposition includes deposition of silicon nitride on the surfaces of the insulators 44 and 46 and subsequent radical oxidation of the silicon nitride.

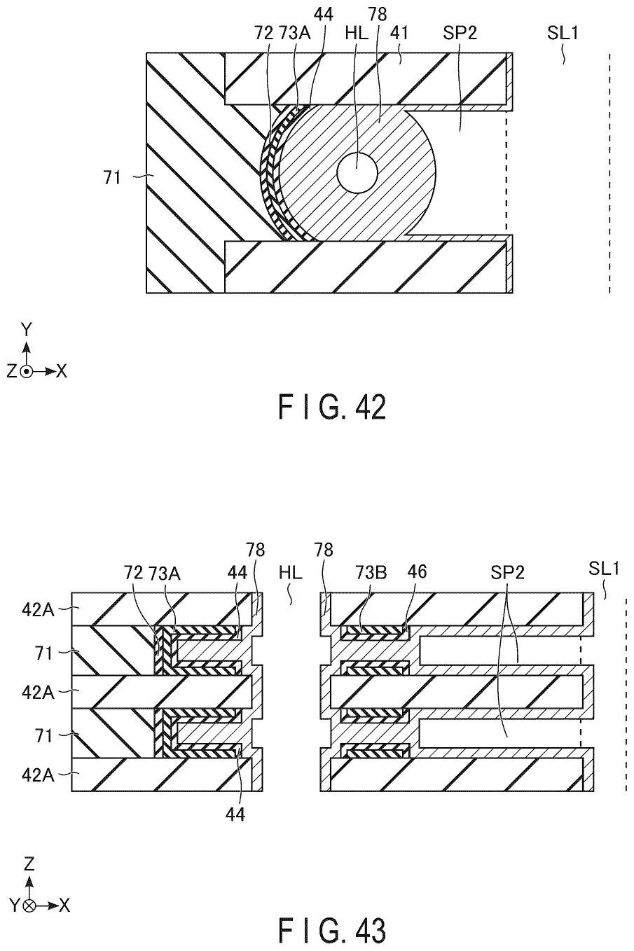

As shown in FIGS. 42 and 43, a sacrificial material 78 is deposited on the surfaces of components that define the hole HL and the spaces SP1 and SP2. The sacrificial material 78 is deposited on portions of each insulator 42A exposed in the hole HL, the space SP1, and the space SP2, and on the surface of the insulators 44 and 46. A region of the space SP1 surrounded by the insulator 44 is buried by the sacrificial material 78. A region of the space SP1 between two insulators 46 is buried by the sacrificial material 78 because the distance between the insulators 46 is small. On the other hand, the space SP2 is not buried and partially remains. In one example, the sacrificial material 78 contains titanium nitride. An example of a method of depositing the sacrificial material 78 includes CVD.

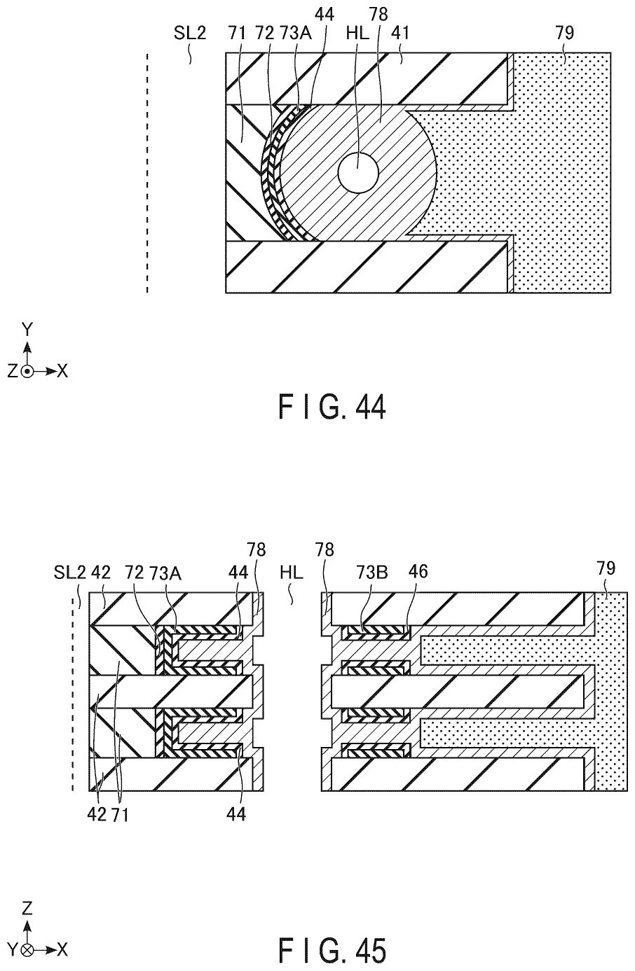

As shown in FIGS. 44 and 45, the slit SL1 and the spaces SP2 are buried by a sacrificial material 79. In one example, the sacrificial material 79 contains amorphous silicon. Examples of a method of depositing the sacrificial material 79 includes CVD.

A slit SL2 is formed in the insulators 42A and the sacrificial materials 71. The slit SL2 spreads along the YZ plane and extends through the insulators 42A and the sacrificial materials 71. The slit SL2 is located in a region where a first portion 21a of a conductor 21 and an insulator 43 are planned to be formed. Examples of a method of forming the slit SL2 include a lithography process and anisotropic etching such as RIE. When the slit SL2 is formed, insulators 42 are formed from the insulators 42A.

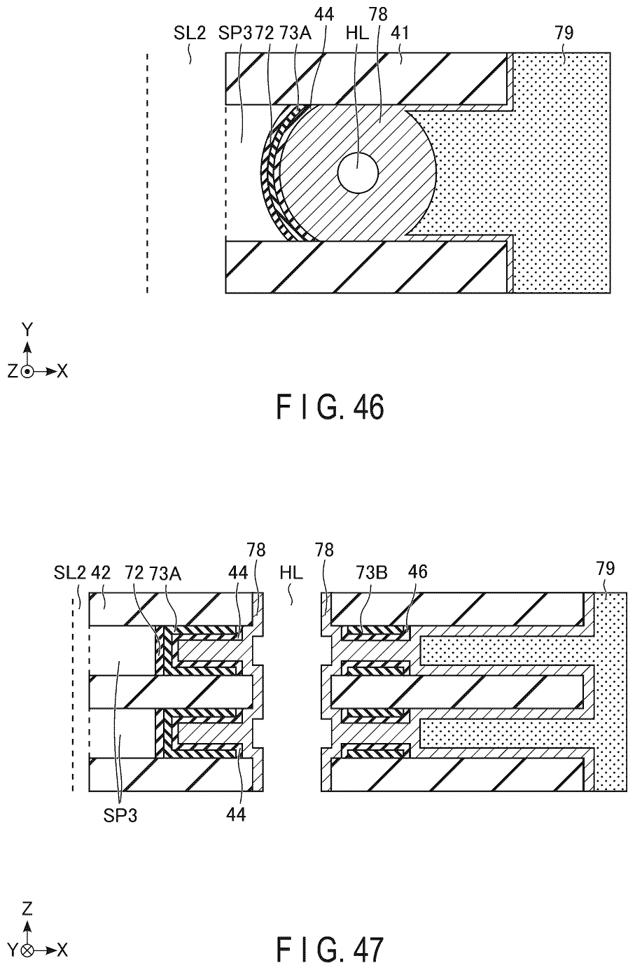

As shown in FIGS. 46 and 47, the sacrificial materials 71 are removed. By the removal, a space SP3 is formed in a region where each sacrificial material 71 was located. In the space SP3, the sacrificial material 72 is exposed. Examples of a method of removing the sacrificial materials 71 include wet etching.

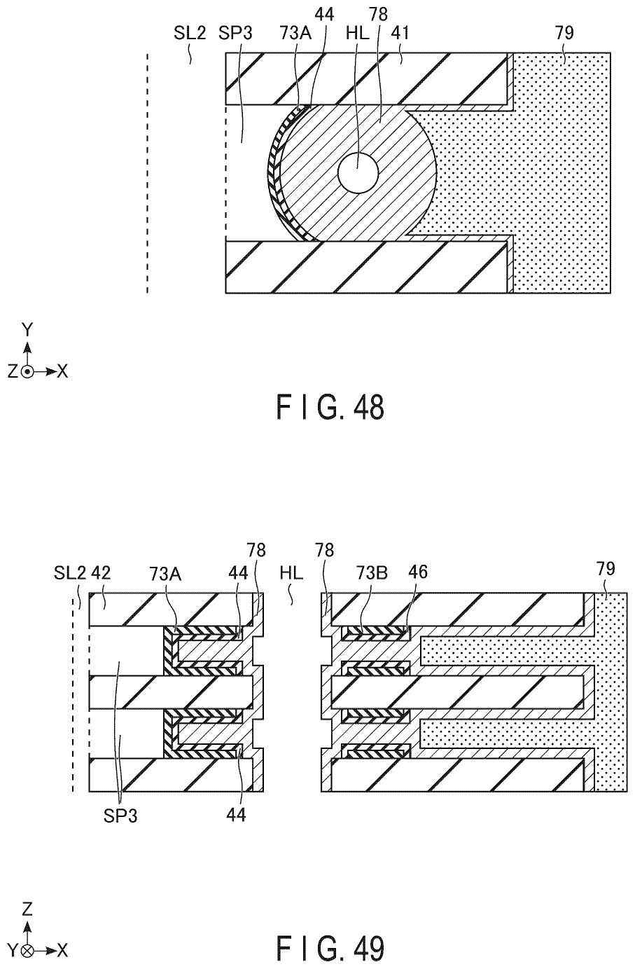

As shown in FIGS. 48 and 49, the sacrificial materials 72 are removed. By the removal, the sacrificial material 73A is exposed in each space SP3. Examples of a method of removal include wet etching.

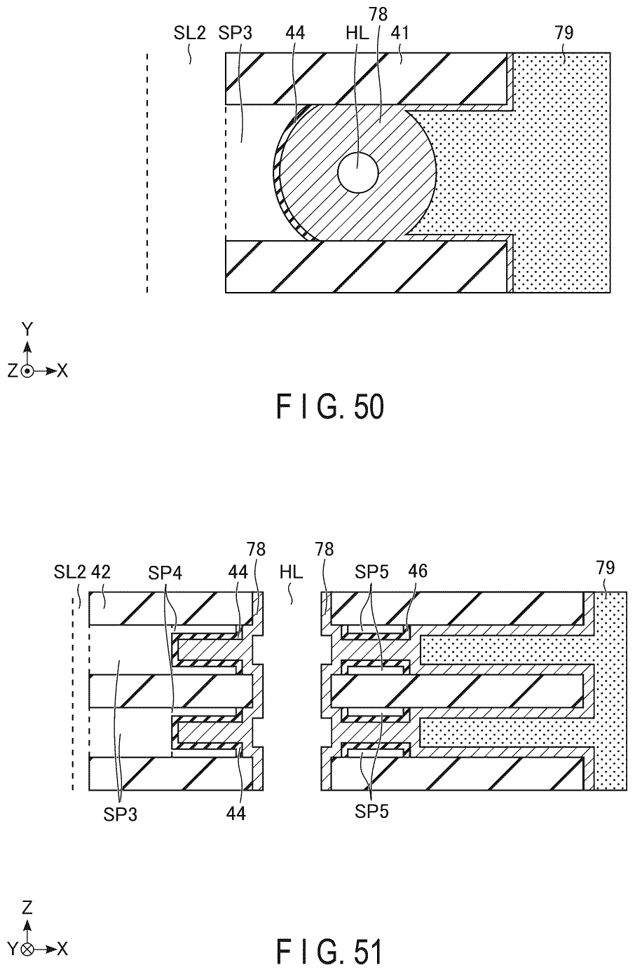

As shown in FIGS. 50 and 51, the sacrificial materials 73B are removed, and the sacrificial materials 73A are partially removed. Examples of a method of removal include wet etching. A chemical solution of wet etching reaches from the space SP3 to the sacrificial material 73A and partially removes the sacrificial material 73A. The chemical solution removes a portion of the sacrificial material 73A between the insulator 44 and the insulator 42. Along with the progress of removal of the sacrificial material 73A, the chemical solution reaches the sacrificial material 73B connected to the sacrificial material 73A and removes the sacrificial material 73B. By the partial removal of the sacrificial materials 73A, a space SP4 is formed in a region where each sacrificial material 73A was located. The space SP4 is connected to the space SP3. By the removal of the sacrificial materials 73B, a space SP5 is formed in a region where each sacrificial material 73B was located. Based on the coupling between the sacrificial material 73B and the sacrificial material 73A, the space SP5 is connected to the space SP4.

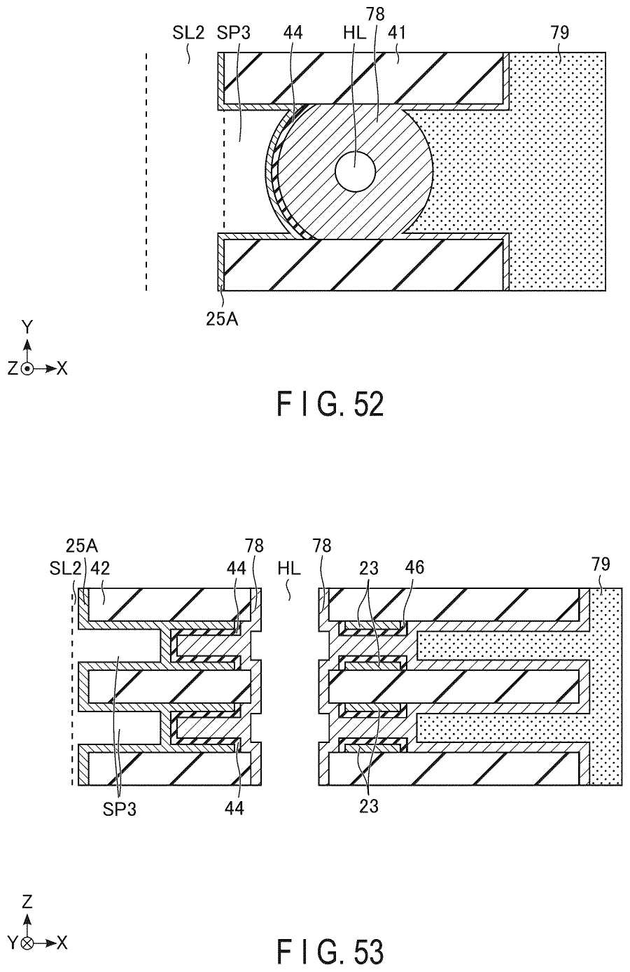

As shown in FIGS. 52 and 53, a conductor 25A is deposited on the surfaces of components that define the slit SL2 and the spaces SP3. The conductor 25A is a component to be processed to a conductor 25 later. The conductor 25A is located on portions of the insulators 41 and 42 exposed in the slit SL2 and the spaces SP3. Also, the conductor 25A is located on portions of the insulators 44 exposed in the spaces SP3. In addition, the conductor 25A buries the spaces SP4. Furthermore, the conductor 25A buries the spaces SP5 connected to the spaces SP4, and conductors 23 are thus formed. The conductor 25A is made of the same material as that of the conductors 25 and 23. Examples of a method of depositing the conductor 25A include CVD.

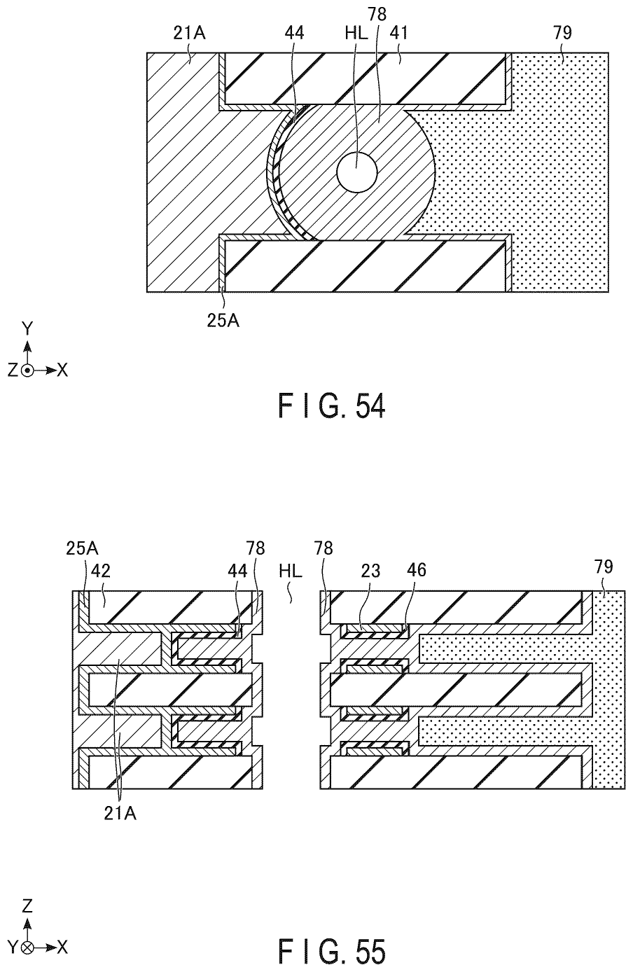

As shown in FIGS. 54 and 55, a conductor 21A is deposited. The conductor 21A is a component to be processed to a conductor 21 later. The conductor 21A buries the slit SL2 and the spaces SP3.

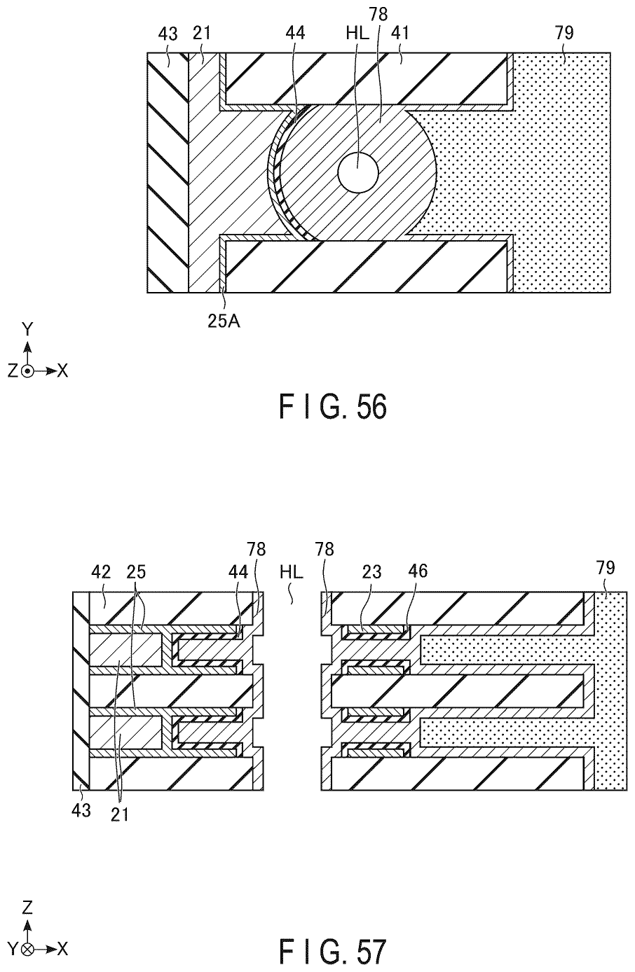

As shown in FIGS. 56 and 57, the conductor 21A and the conductor 25A are partially removed. That is, portions of the conductor 25A located on the insulators 42 in the slit SL2 are removed. In addition, portions of the conductor 21A, located, in a direction away from the hole HL, on the side surfaces of the insulators 42 on the opposite side of the hole HL are removed. By the removal, the slit SL2 is partially formed again, the conductors 21 are formed from the conductor 21A, and the conductors 25 are formed from the conductor 25A. Examples of a method of partially removing the conductor 21A and the conductor 25A include a set of a lithography process and anisotropic etching such as RIE.

Next, the slit SL2 is buried by the insulator 43. Examples of a method of burying include CVD.

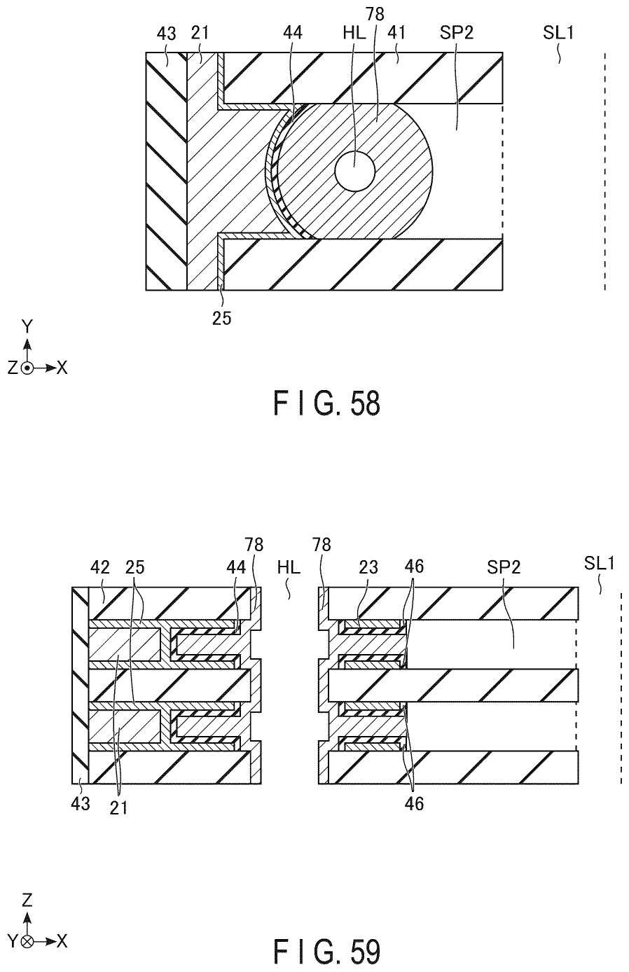

As shown in FIGS. 58 and 59, the sacrificial material 79 is removed. By the removal, the spaces SP2 and the slit SL1 are formed again, and the sacrificial material 78 is exposed in the spaces SP2 and the slit SL1. Examples of a method of removal include wet etching.

Portions of the sacrificial material 78 exposed in the spaces SP2 and the slit SL1 are removed. The removal is performed such that the portions of the sacrificial material 78 burying between the insulators 46 are left. Examples of a method of partially removing the sacrificial material 78 include wet etching.

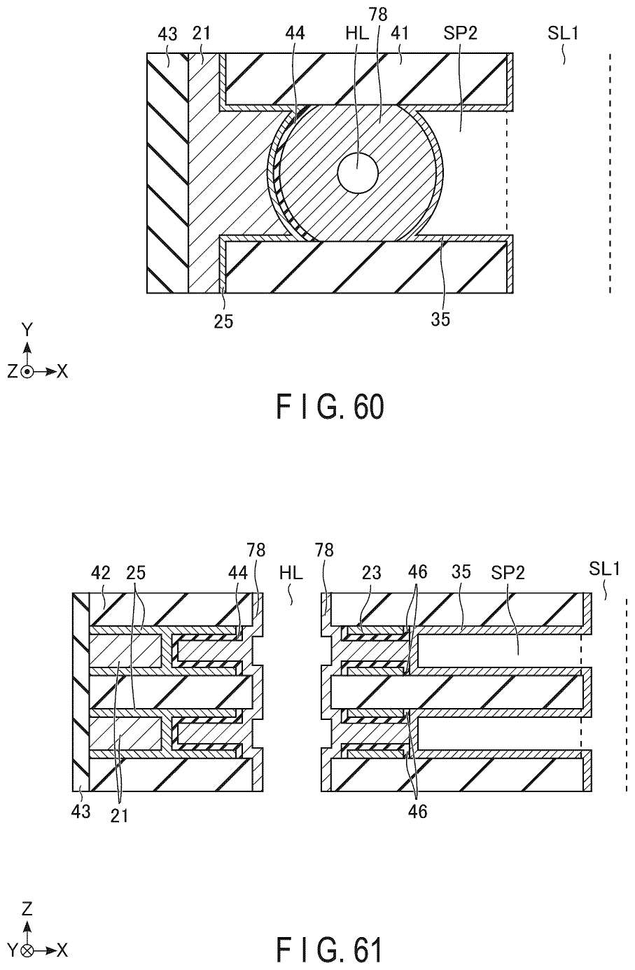

As shown in FIGS. 60 and 61, the conductor 35 is deposited. The conductor 35 covers portions of the surfaces of the insulators 42 exposed in the slit SL1 and the spaces SP2. The conductor 35 covers portions of the surfaces of the insulators 41 exposed in the slit SL1 and the spaces SP2. The conductor 35 covers portions of the surfaces of the insulators 46 exposed in the spaces SP2. The conductor 35 covers portions of the sacrificial material 78 exposed in the spaces SP2 (portions between the insulators 46). Examples of a method of depositing the conductor 35 include CVD.

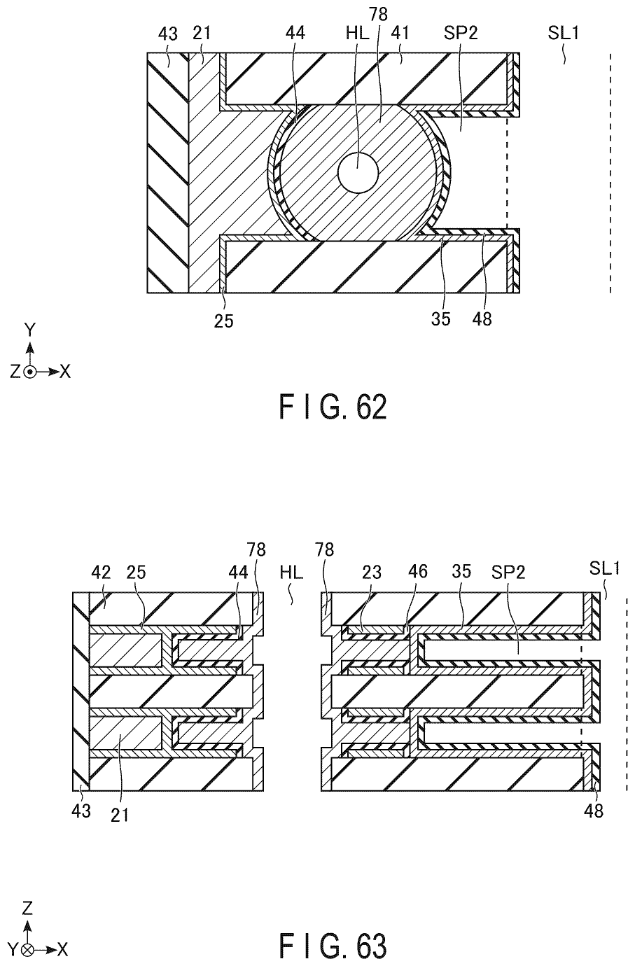

As shown in FIGS. 62 and 63, the insulator 48 is deposited on the surface of the conductor 35. Examples of a method of depositing the insulator 48 include CVD.

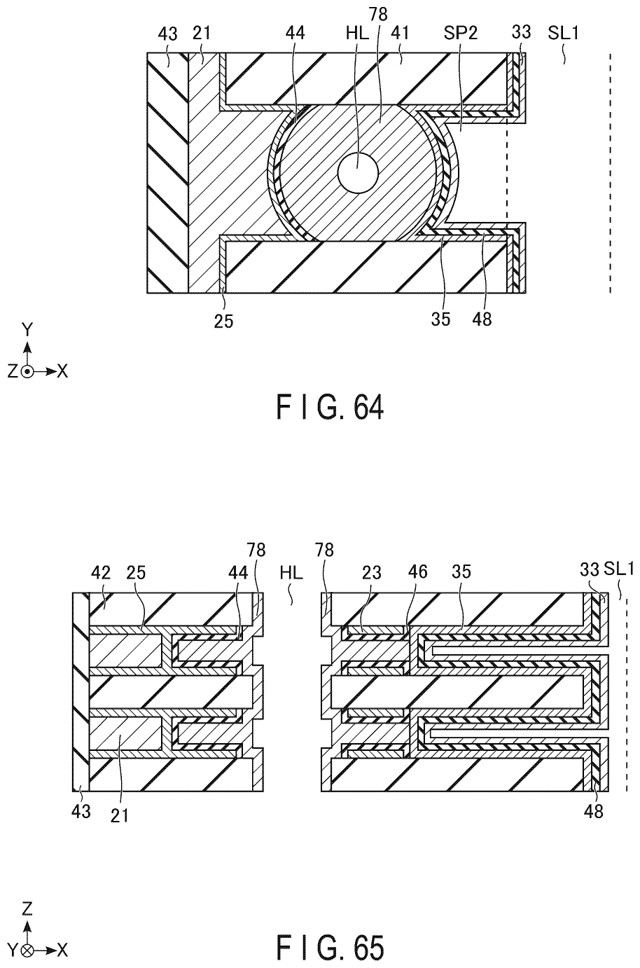

As shown in FIGS. 64 and 65, the conductor 33 is deposited. The conductor 33 covers the surface of the insulator 48 and buries the spaces SP2. Examples of a method of depositing the conductor 33 include CVD.

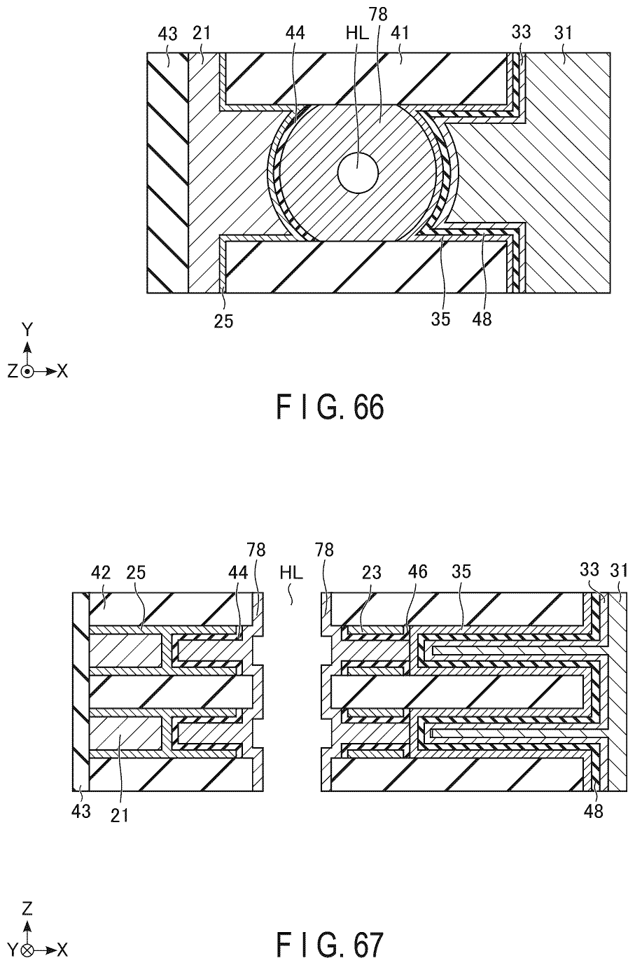

As shown in FIGS. 66 and 67, the conductor 31 is deposited. The conductor 31 buries the slit SL1. Examples of a method of depositing the conductor 31 include CVD.

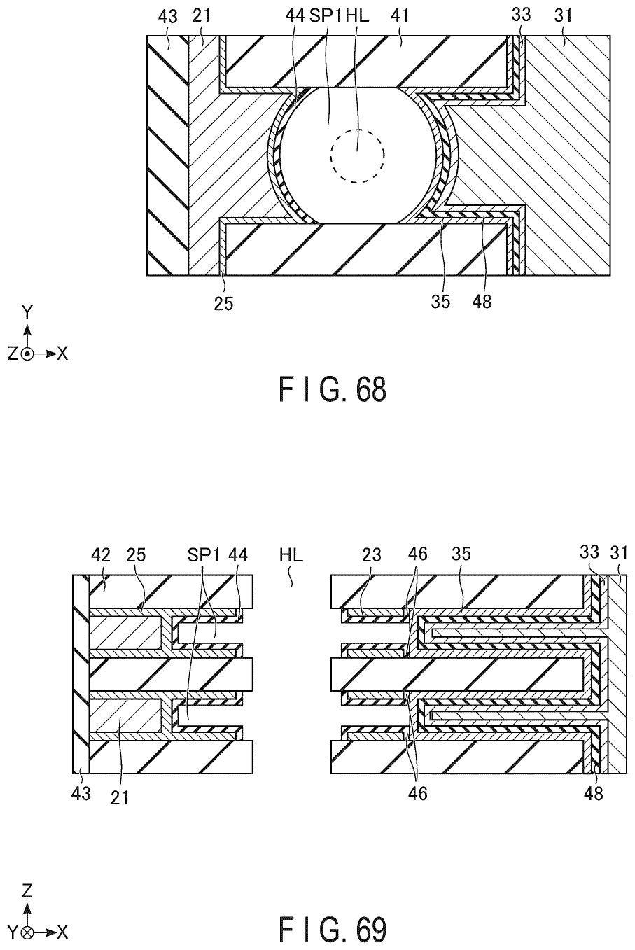

As shown in FIGS. 68 and 69, the sacrificial material 78 is removed. By the removal, the spaces SP1 are partially formed again, and the insulators 44 and 46 are exposed in the spaces SP1. Also, by the removal, the conductor 35 is exposed in the spaces SP1. Examples of a method of removing the sacrificial material 78 include wet etching.

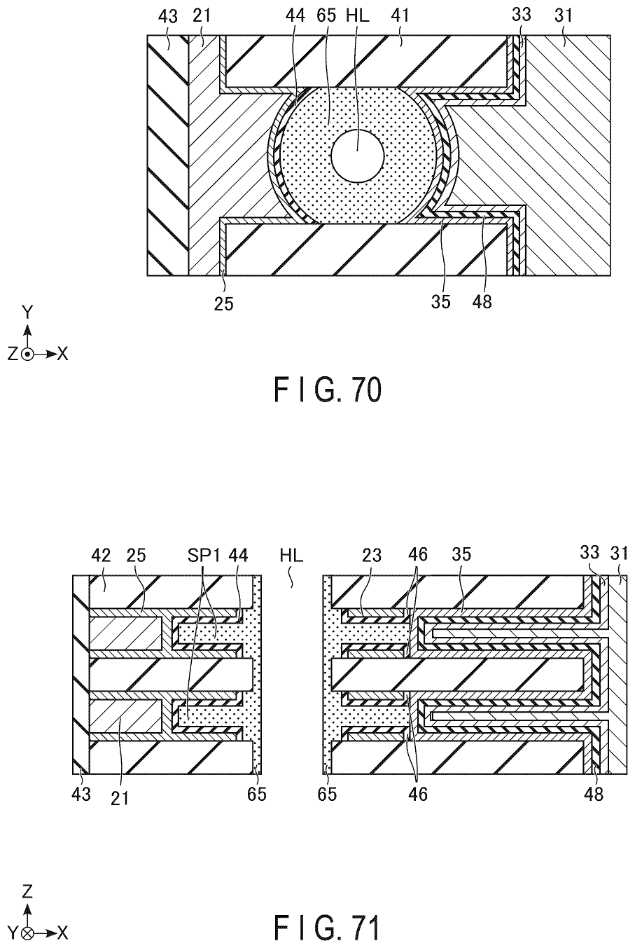

As shown in FIGS. 70 and 71, the semiconductor 65 is deposited. The semiconductor 65 buries the spaces SP1 and contacts the conductors 35. The semiconductor 65 is deposited on portions of the insulators 42 exposed in the hole HL. The semiconductor 65 does not bury the hole HL.

As shown in FIGS. 5, 6, and 7, a conductor 63 is deposited. The conductor 63 is deposited on a portion of the semiconductor 65 exposed in the hole HL.

### 1.3. Advantages (Advantageous Effects)

According to the first embodiment, the memory device 1 having a high electrical characteristic is provided, as will be described below in detail.

It is considered that, for the sake of comparison, a memory device for reference is manufactured by the following process. That is, the material of a gate electrode is deposited on a structure obtained by the steps described above with reference to FIGS. 12 and 13 of the first embodiment. The material of the gate electrode covers the surfaces of the insulator 42A and the sacrificial materials 71. Next, the material of the gate electrode is partially removed and processed to the same shape as the shape of the conductor 23 according to the first embodiment. Next, a gate insulator is formed on the gate electrode.

For the purpose of obtaining high reliability, the gate insulator is preferably formed by oxidizing silicon nitride that covers the gate electrode. However, in some combinations of the gate electrode material and the material of silicon nitride used to form the gate insulator, it is impossible to obtain a sufficiently large selectivity to oxidation between the gate electrode material and the silicon nitride. For this reason, in oxidation of the process of forming the gate insulator, the gate electrode is unintentionally oxidized. This lowers the reliability of the gate electrode. In addition, since the gate electrode is covered with the gate insulator, the gate electrode and the word line to be deposited later in contact with the gate electrode are formed by different steps. This lowers an electrical characteristic such as the electric resistance of the gate electrode and the word line.

According to the first embodiment, the sacrificial material 73 is formed in a region where the conductor 23 (gate electrode) is planned to be formed, the sacrificial material 73 is covered with the insulator 46 (gate insulator), the sacrificial material 73 is removed, and a conductor is buried in the region where the sacrificial material 73 was located and formed in a region where the conductor 25 functioning as a part of the word line is to be formed, thereby forming the conductor 25 and the conductor 23 by the common process. For this reason, the conductors 25 and 23 are formed as different portions of a single conductor, include no seam, and have a common crystal orientation. Hence, the memory device 1 has a high electrical characteristic.

Also, the conductors 25 and 23 are formed after formation of the insulator 46. For this reason, the insulator 46 and the conductors 25 and 23 can each be formed by an optimum step while suppressing influence to each other. From this viewpoint as well, the memory device 1 has a high electrical characteristic.

### 2. SECOND EMBODIMENT

The second embodiment is related to the shape of an insulator 41.

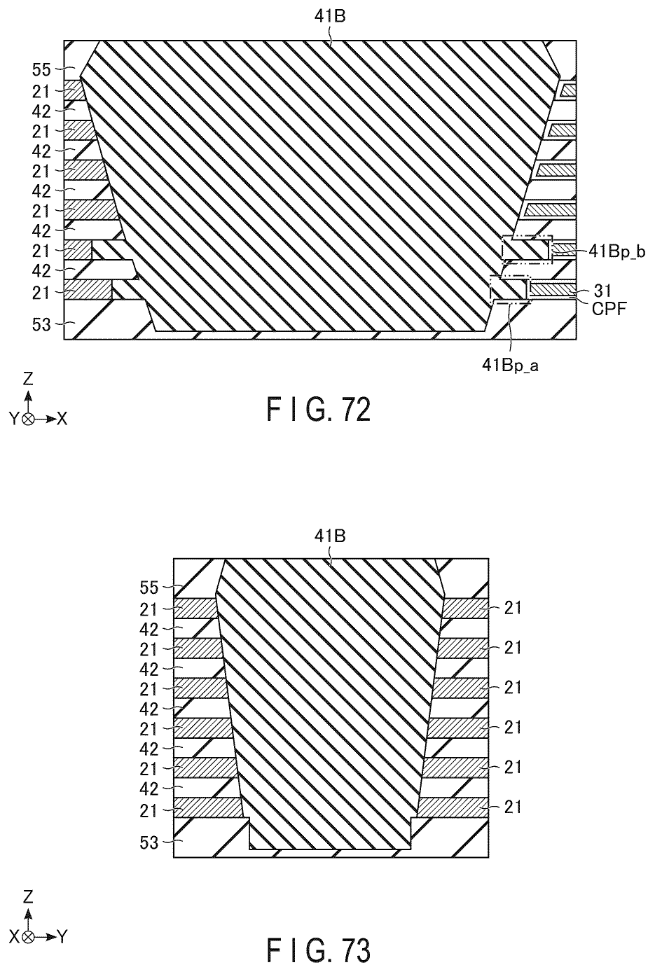

FIGS. 72 and 73 each illustrate the structure of a section of a part of a memory device according to the second embodiment, and show the section of an insulator 41B according to the second embodiment. FIG. 72 shows a section along the XZ plane. FIG. 73 shows a section along the YZ plane. The size of a component in the X direction may be referred to as an X size and the size in the Y direction may be referred to as a Y size hereinafter.

As shown in FIG. 72, the insulator 41B has, along the XZ plane, an inverted tapered shape in a portion including the upper end (or an upper portion). In a component having the inverted tapered shape, the size in a first direction at a position farther in the Z direction is smaller than the size in the first direction at a position farther in the −Z direction. That is, in the upper portion, the X size of the insulator 41B at a position farther in the Z direction is smaller than the X size at a position farther in the −Z direction.

The insulator 41B has, along the XZ plane, a tapered shape in a portion including the lower end (or a lower portion). In a component having the tapered shape, the size in a first direction at a position farther in the Z direction is larger than the size in the first direction at a position farther in the −Z direction. That is, in the lower portion, the X size of the insulator 41B at a position farther in the Z direction is larger than the X size at a position farther in the −Z direction.

The insulator 41B includes a first projecting portion 41Bp_a and a second projecting portion 41Bp_b. The first projecting portion 41Bp_a is located in a lowermost memory layer ML (that is, a layer in which a conductor 21 is located). The first projecting portion 41Bp_a on the side in the X direction projects in the X direction. The first projecting portion 41Bp_a on the side in the −X direction projects in the −X direction.

The second projecting portion 41Bp_b is located in the second memory layer ML from the lowermost one. The second projecting portion 41Bp_b on the side in the X direction projects in the X direction. The second projecting portion 41Bp_b on the side in the −X direction projects in the −X direction.

The insulator 41B is in contact with a stacked film CPF at an end on the side in the X direction. The insulator 41B is in contact with a set of conductors 21 and 25 at an end on the side in the −X direction. The conductor 25 is not illustrated.

The projecting portions may be provided in three or more memory layers ML.

As shown in FIG. 73, the maximum Y size of the insulator 41B is smaller than the maximum X size. The insulator 41B has, along the YZ plane, an inverted tapered shape in the upper portion. That is, in the upper portion, the Y size of the insulator 41B at a position farther in the Z direction is smaller than the Y size at a position farther in the −Z direction. The angle of the inverted taper (the angle with respect to the z-axis) concerning the Y size of the insulator 41B in the upper portion is smaller than the angle of the inverted taper concerning the X size of the insulator 41B in the upper portion.

The insulator 41B has, along the YZ plane, a tapered shape in the lower portion. That is, in the lower portion, the Y size of the insulator 41B at a position farther in the Z direction is larger than the Y size at a position farther in the −Z direction. The angle of the taper concerning the Y size of the insulator 41B in the lower portion is smaller than the angle of the taper concerning the X size of the insulator 41B in the lower portion.

The insulator 41B includes no projecting portions at an end on the side in the Y direction and at an end on the side in the −Y direction. The insulator 41B is in contact with the set of the conductors 21 and 25 at the end on the side in the Y direction and at the end on the side in the −Y direction. The conductor 25 is not illustrated.

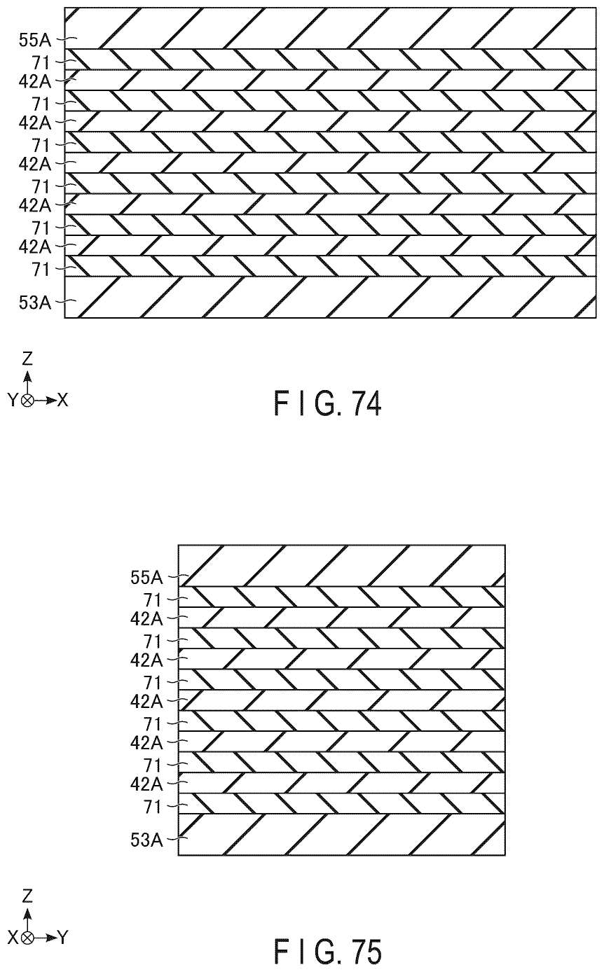

FIGS. 74, 75, 76, 77, 78, 79, 80, 81, 82, and 83 each illustrate the section of the structure of a part in the manufacturing steps of the memory device according to the second embodiment. Steps to be described with reference to FIGS. 74, 75, 76, 77, 78, 79, 80, 81, 82, and 83 correspond to some of the steps described above with reference to FIGS. 8 and 9 in the first embodiment.

FIGS. 74, 76, 78, 80, and 82 each show the region shown in FIG. 72.

FIGS. 75, 77, 78, 81, and 83 each show the region shown in FIG. 73.

As shown in FIGS. 74 and 75, an insulator 53A is deposited on a substrate 51 (not shown), and a sacrificial material 71 and an insulator 42A are alternately deposited one by one above the insulator 53A. Next, an insulator 55A is deposited on the uppermost sacrificial material 71. The insulator 53A is a component to be processed to an insulator 53 by a later step, and contains the same material as the insulator 53. The insulator 55A is a component to be processed to an insulator 55 by a later step, and contains the same material as the insulator 55. Examples of a method of deposition include CVD.

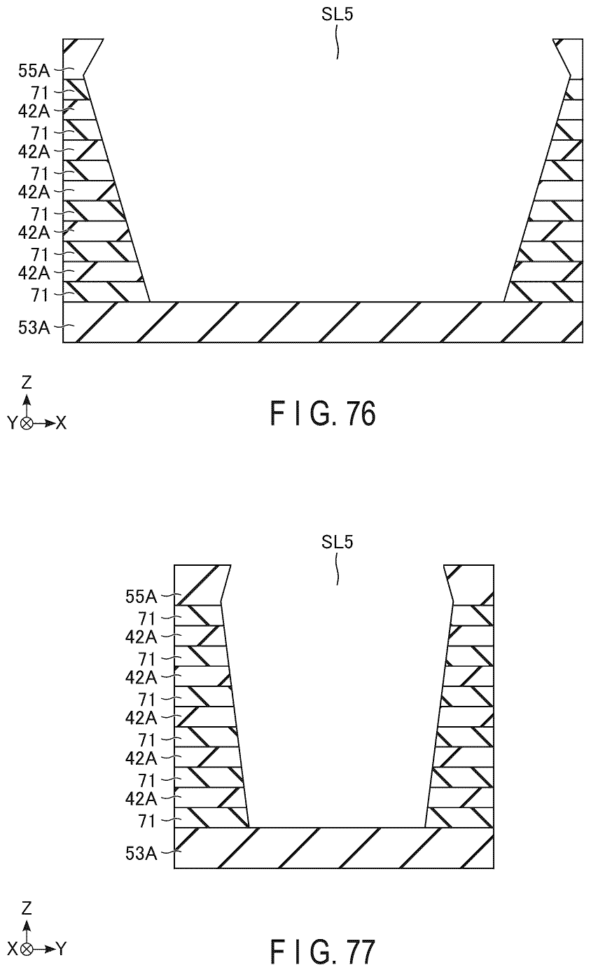

As shown in FIGS. 76 and 77, a slit SL5 is formed. The slit SL5 is formed in a region where an insulator 41B is planned to be formed. The slit SL5 has an inverted tapered shape at ends in the X direction, −X direction, Y direction, and −Y direction in the upper portion, like the shape of the insulator 41B. Also, the slit SL5 has a tapered shape at ends in the X direction, −X direction, Y direction, and −Y direction in the lower portion, like the shape of the insulator 41B. The slit SL5 reaches the lower surface of the lowermost sacrificial material 71.

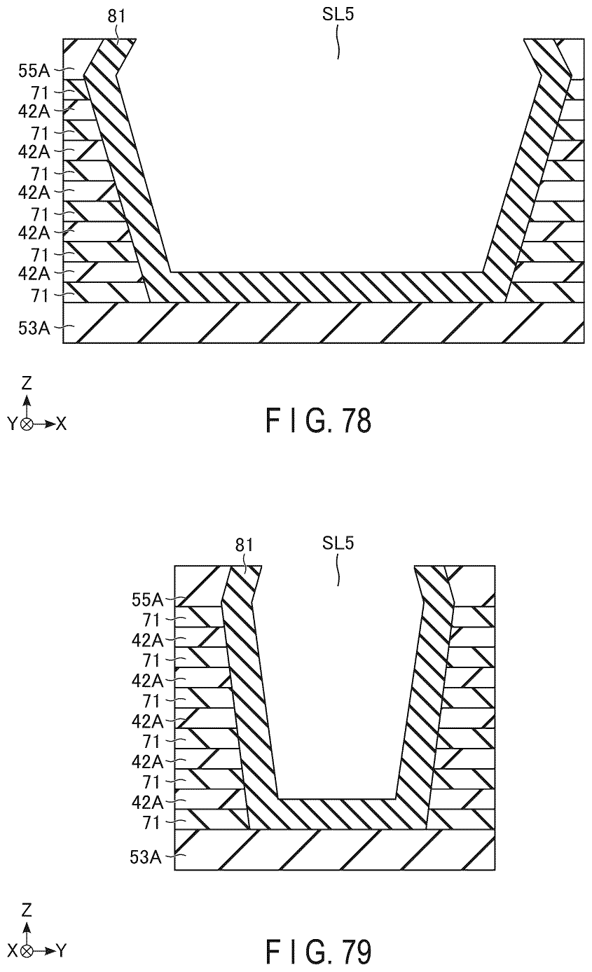

As shown in FIGS. 78 and 79, a protective film 81 is deposited on the surfaces of components that define the slit SL5. The protective film 81 is deposited on portions of the surfaces of the insulators 53A, 42A, and 55 and the sacrificial materials 71 exposed in the slit SL5. In one example, the protective film 81 contains the same material as the material of the insulator 42A. Examples of a method of depositing the protective film 81 include CVD.

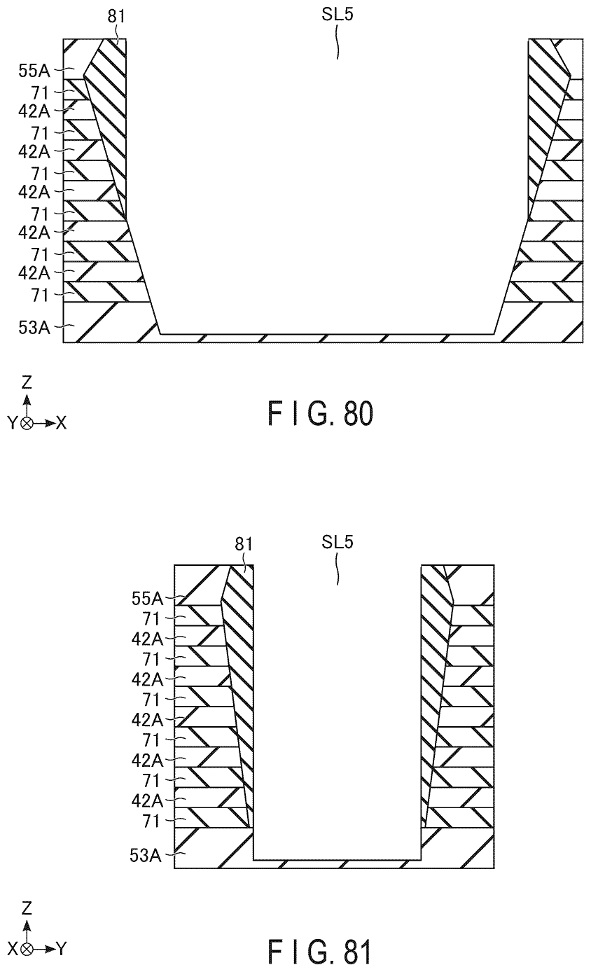

As shown in FIGS. 80 and 81, the protective film 81 is partially removed by anisotropic etching such as RIE. The angle of the taper at ends of the lower portion of the slit SL5 in the X and −X directions is large. For this reason, portions of the protective film 81 located in the −Z direction, particularly in some layers from the lowermost layer, including the lowermost layer, on the sacrificial materials 71 and the insulators 42A are removed by etching. Thus, the sacrificial materials 71 and the insulators 42A are exposed in the lower portion of the slit SL5. On the other hand, the protective film 81 remains in the upper portion of the slit SL5. The upper portion of the insulator 53A is removed by etching, and the insulator 53 is formed from the insulator 53A.

The angle of the taper of the lower portion of the slit SL5 at the ends on the sides in the Y and −Y directions is small. For this reason, only a little amount of the protective film 81 is removed by etching. Hence, the portions of the protective film 81 at the ends on the sides in the Y and −Y directions remain even in the lower portion of the slit SL5. That is, portions of the surfaces of the sacrificial materials 71 and the insulators 42A exposed at the ends on the sides in the Y and −Y directions in the slit SL5 are still covered with the protective film 81.

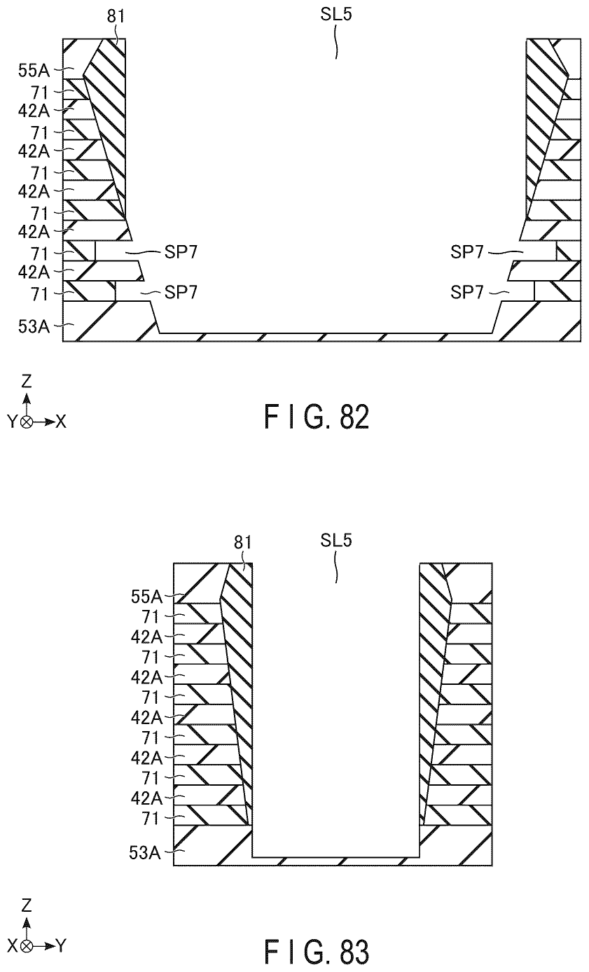

As shown in FIGS. 82 and 83, the sacrificial materials 71 are partially removed. Removal is performed by isotropic etching, and examples of a method of removal include wet etching. A chemical solution of wet etching removes portions of the sacrificial materials 71 exposed in the slit SL5. Thus, the sacrificial materials 71 that are not covered with the protective film 81 (the sacrificial materials 71 exposed in the lower portion of the slit SL5) are partially removed from the center of the slit SL5 in the X and −X directions. As a result, a space SP7 is formed in each removed portion of the sacrificial material 71.

On the other hand, the sacrificial materials 71 covered with the protective film 81 are not removed by wet etching. Hence, removal of the sacrificial material 71 does not progress in the X and −X directions in the upper portion of the slit SL5. In addition, removal of the sacrificial material 71 does not progress in the Y and −Y directions. Hence, the spaces SP7 extending in the Y and −Y directions are not formed even in the lower portion of the slit SL5.

As shown in FIGS. 72 and 73, remaining portions of the slit SL5 and the spaces SP7 are buried by the material of an insulator 41B. After that, components including a cell capacitor CC and a transistor CT are formed.

According to the second embodiment, an unintended short circuits of components is suppressed, as will be described later in detail.

A structure for reference will be described below for the sake of comparison. The insulator 41B plays a role of separating two components (for example, semiconductors 65) sandwiching the insulator 41B in the Y direction and preventing these from being connected to each other. For this purpose, when forming two spaces (for example, the spaces SP2 in the first embodiment) where the two components are planned to be provided, it is necessary that the insulator 41B prevents the two spaces from being connected.

The structure for reference includes an insulator 141B in place of the insulator 41B. A slit that defines the shape of the insulator 141B inevitably has a tapered shape in the lower portion due to the characteristics unique to anisotropic etching, as described above concerning the slit SL5. For this reason, the XY plane shape of the lower portion of the insulator 141B is smaller than the XY plane shape of the upper portion. Hence, the two spaces may be connected in the region where the insulator 141B should exist, and this leads to coupling of the components formed in the spaces. To prevent this, it is considered that the shape of the insulator 141B, in turn, the shape of the slit SL5 is made large as a whole. However, this reduces a region where memory cells and interconnects are arranged and makes the interval of components narrow.

According to the second embodiment, the insulator 41B includes projecting portions 41Bp in the lower portion. The projecting portions 41Bp extend from the insulator 41B in the X and −X directions. For this reason, the insulator 41B has a large X size even in the lower portion where the X size is small because of the tapered shape. Hence, the insulator 41B can prevent the components on both sides of the insulator 41B, which should be insulated from each other, from being connected even in the lower portion.

Also, the insulator 41B does not project at the ends on the sides in the Y and −Y directions. Hence, an excessively narrow interval between the insulator 41B and a component (for example, the semiconductor 65) arranged in the Y direction is suppressed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory device comprising:
a semiconductor that spreads along a first plane including a first direction and a second direction which cross each other, has an annular shape, includes a first portion on a side in the first direction, and includes a second portion on a side opposite to the first direction;
a first insulator on the first portion of the semiconductor;
a second insulator on the second portion of the semiconductor;
a first conductor that is provided farther in a third direction crossing the first direction and the second direction than the first insulator and the second insulator, and includes a first conductor including a first portion facing the first portion of the semiconductor via the first insulator;
a second conductor that contacts the first conductor;
a third conductor that contacts the first portion of the semiconductor;
a third insulator that sandwiches the third conductor together with the first portion of the semiconductor; and
a fourth conductor that sandwiches the third insulator together with the third conductor.

2. The device according to claim 1, further comprising
a fifth conductor that extends in the third direction and is surrounded by the semiconductor along the first plane.

3. The device according to claim 1, further comprising
a fourth insulator that is provided farther in the third direction than the first portion and the second portion of the semiconductor and includes a hole extending in the third direction.

4. The device according to claim 3, wherein
the semiconductor surrounds the hole along the first plane.

5. The device according to claim 4, further comprising
a fifth conductor that extends in the third direction and is surrounded by the semiconductor along the first plane,
wherein the semiconductor further includes a third portion that surrounds the fifth conductor along the first plane, and
the third portion of the semiconductor extends in the third direction, is connected to the first portion and the second portion, and contacts the fourth insulator in the hole.

6. The device according to claim 3, wherein
the first insulator does not contact the fourth insulator in the hole.

7. The device according to claim 6, wherein
the second insulator does not contact the fourth insulator in the hole.

8. The device according to claim 3, wherein
the first conductor is located between the semiconductor and the fourth insulator.

9. The device according to claim 3, further comprising
a fifth insulator on the first portion of the semiconductor farther in a fourth direction opposite to the third direction than the first insulator,
wherein the first conductor further includes a second portion, and
the second portion of the first conductor is provided farther in the fourth direction than the first insulator and the second insulator, and faces the first portion of the semiconductor via the fifth insulator.

10. The device according to claim 9, wherein
the second insulator includes a second portion which is on the first portion of the semiconductor and propositioned farther in the fourth direction than the first portion of the semiconductor,
the first conductor further includes a third portion, and
the third portion of the first conductor is provided farther in the fourth direction than the second portion of the semiconductor, and faces the second portion of the semiconductor via the second portion of the second insulator.

11. The device according to claim 10, further comprising
a sixth insulator that is provided farther in the fourth direction than the first portion and the second portion of the semiconductor and includes a second hole connected to the hole.

12. The device according to claim 11, wherein
the third portion of the semiconductor contacts the sixth insulator in the second hole.

13. The device according to claim 12, wherein
the fifth insulator does not contact the sixth insulator in the second hole.

14. The device according to claim 12, wherein
the second insulator does not contact the sixth insulator in the second hole.

15. The device according to claim 1, wherein
the semiconductor includes an oxide semiconductor.

16. A memory device comprising:
a plurality of first insulators arranged in a first direction at an interval;
a semiconductor that extends through the plurality of first insulators in the first direction and includes a first portion projecting in a second direction crossing the first direction between two adjacent first insulators of the plurality of first insulators;
a second insulator on the first portion of the semiconductor;
a first conductor between one of the plurality of first insulators and the second insulator;
a second conductor that contacts the first portion of the semiconductor;
a third insulator that sandwiches the second conductor together with the first portion of the semiconductor;
a third conductor that sandwiches the third insulator together with the second conductor; and
a fourth insulator that extends through the plurality of first insulators in the first direction and extends in the second direction,
wherein an end of the fourth insulator on a side in the second direction in a portion on a side in the first direction is located farther in the second direction at a position farther in the first direction, and
an end of the fourth insulator on the side in the second direction in a portion on a side opposite to the first direction includes a first portion projecting in the second direction.

17. The device according to claim 16, wherein
the first portion of the fourth insulator is located in a layer in which the first portion of the semiconductor is located.

18. The device according to claim 16, wherein
an end of the fourth insulator on a side in a third direction in the portion on the side in the first direction is located farther in the third direction at a position farther in the first direction, and
the third direction crosses the first direction and the second direction.

19. The device according to claim 18, wherein
the end of the fourth insulator on the side in the third direction does not include a portion projecting in the third direction.

20. The device according to claim 16, wherein
the first portion of the fourth insulator is located in a layer adjacent to one of the plurality of first insulators, which is located farthest in a fourth direction, and
the fourth direction faces opposite to the first direction.
